(19) United States
(12) Patent Application Publication
(10) Pub. No.: US 2026/0047328 A1
(43) Pub. Date: Feb. 12, 2026

(54) MICROFLUIDIC TRANSFER SUBSTRATE, MICROFLUIDIC TRANSFER DEVICE, AND MICROFLUIDIC TRANSFER APPARATUS

(71) Applicant: HKC CORPORATION LIMITED, SHENZHEN (CN)

(72) Inventors: Zeyao LI, SHENZHEN (CN); Pei XU, SHENZHEN (CN)

(73) Assignee: HKC CORPORATION LIMITED, SHENZHEN (CN)

(21) Appl. No.: 19/285,094

(22) Filed: Jul. 30, 2025

(30) Foreign Application Priority Data
Aug. 9, 2024 (CN) 202411090163.3

(51) Int. Cl. H10K 71/13

(52) U.S. Cl. CPC H10K 71/13

(57) ABSTRACT

A microfluidic transfer substrate includes a plurality of first pixel units. Some of the plurality of first pixel units serve as first microfluidic pixels, each first microfluidic pixel define a through hole, the others of the plurality of first pixel units serve as second microfluidic pixels, and each second microfluidic pixel is free of the through hole. Each first microfluidic pixel is adjacent to at least one second microfluidic pixel. A microfluidic transfer device and a microfluidic transfer apparatus are further provided.

### CROSS-REFERENCE TO RELATED APPLICATIONS

The present application claims priority to Chinese Patent Application No. 202411090163.3, entitled “MICROFLUIDIC TRANSFER SUBSTRATE, MICROFLUIDIC TRANSFER DEVICE, AND MICROFLUIDIC TRANSFER APPARATUS”, filed on Aug. 9, 2024, which is herein incorporated by reference in its entirety.

### TECHNICAL FIELD

The present disclosure relates to the technical field of display, and in particular to a microfluidic transfer substrate, a microfluidic transfer device, and a microfluidic transfer apparatus.

### BACKGROUND

Organic light-emitting diode (OLED) display panels have many advantages, such as self-luminosity, a low driving voltage, high light-emitting efficiency, short response time, high clarity and contrast, a viewing angle of nearly 180°, a wide operating temperature range, the ability to achieve flexible and large-area full-color displays, etc. The OLED display panels are widely recognized as the most promising display devices in the industry.

A structure of the OLED display panel generally includes a substrate, an anode on the substrate, a cathode on the anode, and a light-emitting element layer sandwiched between the anode and the cathode. A preparation method for the light-emitting element layer usually includes vacuum thermal evaporation and solution process. The solution process involves treating the required materials, such as dispersing the required materials into nanoscale particles, dissolving them in a corresponding solution to form ink, and then using a film-forming device to deposit the ink on a surface of a substrate. After solvent evaporates, a desired thin film is formed on the surface of the substrate.

In related art, a specific method of solution process may include ink-jet printing, nozzle printing, roller printing, and spin coating, etc. However, these film-forming methods all have the problem of low film-forming efficiency.

### SUMMARY OF THE DISCLOSURE

A technical solution in the present disclosure is to provide a microfluidic transfer substrate. The microfluidic transfer substrate includes a plurality of first pixel units. Some of the plurality of first pixel units serve as first microfluidic pixels, each first microfluidic pixel define a through hole, the others of the plurality of first pixel units serve as second microfluidic pixels, and each second microfluidic pixel is free of the through hole. Each first microfluidic pixel is adjacent to at least one second microfluidic pixel.

In some embodiments, the plurality of first pixel units are divided into a plurality of pixel groups. Each of the plurality of pixel group consists of one first microfluidic pixel and one second microfluidic pixel, or each of the plurality of pixel group consists of a plurality of first microfluidic pixels and one second microfluidic pixel.

In some embodiments, the plurality of first pixel units are arranged in a two-dimensional array. The pixel units in odd-numbered rows are all the first microfludic pixels, and the first pixel units in even-numbered rows are all the second microfluidic pixels and serve as transport channels; or in every three adjacent rows of first pixel units, the first pixel units in two outer rows are all the first microfluidic pixels, and the first pixel units in a middle row are all the second microfluidic pixels and serve as the transport channels.

In some embodiments, the plurality of first pixel units are arranged in a two-dimensional array. In every three adjacent rows of first pixel units, the first pixel units in an outer row are all the second microfluidic pixels and serve as transport channels, and the first pixel units in the other two rows are divided into a plurality of pixel groups alternately arranged along a row direction. Each of the plurality of pixel groups consists of three first microfluidic pixels and one second microfluidic pixel, and the three first microfluidic pixels of each of the plurality of pixel groups are adjacent to the one second microfluidic pixel.

In some embodiments, the plurality of first pixel units are rectangular, and each of the three first microfluidic pixels of each pixel group shares a side with the one second microfluidic pixel, and a pattern formed by two adjacent pixel groups is centrally symmetric.

In some embodiments, the plurality of first pixel units are arranged in a hexagonal close-packed distribution, and each of the plurality of first pixel units is a circle or a regular hexagon. In every three adjacent rows of first pixel units, the first pixel units in an outer row are all the second microfluidic pixels and serves as transport channels, and the first pixel units in the other two rows are divided into a plurality of pixel groups alternately arranged along a row direction. Each of the plurality of pixel groups consists of three first microfluidic pixels and one second microfluidic pixel, the three first microfluidic pixels and the one second microfluidic pixel are arranged in two rows and two columns with a staggered configuration, and the three first microfluidic pixels of each pixel group are all adjacent to the one second microfluidic pixel.

In some embodiments, the microfluidic transfer substrate has a transfer area and a liquid droplet input area located on a side of the transfer area. The plurality of first pixel units are disposed in the transfer area, and a plurality of second pixel units are disposed in the liquid droplet input area. The plurality of second pixel units have the same structure as the second microfluidic pixels. The liquid droplet input area is communicated with the transport channels, and configured for generating and transporting liquid droplets to the transfer area.

In some embodiments, each of the plurality of first pixel units includes a substrate, a thin film transistor, a first insulation layer, a planarization layer, a microfluidic electrode layer, a second insulation layer, and a hydrophobic layer arranged in sequence. A through hole sequentially penetrates through the substrate, the first insulation layer, the planarization layer, the microfluidic electrode layer, the second insulation layer, and the hydrophobic layer; and the through hole is arranged in a staggered manner with the thin film transistor.

Another technical solution in the present disclosure is to provide a microfluidic transfer device. The microfluidic transfer device includes a microfluidic transfer substrate in any one of above embodiments and a microfluidic control circuit. The microfluidic control circuit is electrically connected to the microfluidic transfer substrate. The microfluidic control circuit is configured to control liquid droplet on the second microfluidic pixels to move into the through holes of the first microfluidic pixels.

Yet another technical solution in the present disclosure is to provide a microfluidic transfer apparatus. The microfluidic transfer apparatus includes a microfluidic transfer device described above, a sealing assembly, and an air pump. The microfluidic transfer device is configured to align with a driving backplane during use. The sealing assembly is configured to seal a space on a side of the microfluidic transfer substrate away from the driving backplane, and/or configured to seal a space between the microfluidic transfer substrate and the driving backplane. The air pump is configured to supply air to the space on the side of the microfluidic transfer substrate away from the driving backplane, and/or to evacuate the space between the microfluidic transfer substrate and the driving backplane.

### BRIEF DESCRIPTION OF THE DRAWINGS

In order to more clearly illustrate the technical solutions in some embodiments of the present disclosure or in the related art, hereinafter, the accompanying drawings that are used in the description of some embodiments or the related art will be briefly described. Obviously, the accompanying drawings in the description below are merely the accompanying drawings in some embodiments of the present disclosure. For those of ordinary skill in the art, other accompanying drawings may be obtained based on these accompanying drawings without any creative efforts.

FIG. 1 is a structural schematic view of a first embodiment of a microfluidic transfer substrate in the present disclosure.

FIG. 2 is a structural schematic view of a second embodiment of a microfluidic transfer substrate in the present disclosure.

FIG. 3 is a structural schematic view of a third embodiment of a microfluidic transfer substrate in the present disclosure.

FIG. 4 is a structural schematic view of a fourth embodiment of a microfluidic transfer substrate in the present disclosure.

FIG. 5 is a cross-sectional structural schematic view of the microfluidic transfer substrate of FIG. 1.

FIG. 6 is a cross-sectional structural schematic view of the microfluidic transfer substrate of FIG. 1 during transfer of a liquid droplet.

FIG. 7 is a structural block view of a microfluidic transfer device in the present disclosure.

FIG. 8 is a structural schematic view of a microfluidic transfer apparatus in an embodiment of the present disclosure.

FIG. 9 is a structural schematic view of a microfluidic transfer apparatus in another embodiment of the present disclosure.

FIG. 10 is a flowchart of a first embodiment of a method for transferring liquid droplets in the present disclosure.

FIG. 11a is a structural schematic view of a structure corresponding to an operation at block S2 in the method for transferring the liquid droplets of FIG. 10.

FIG. 11b is a cross-sectional structural schematic view of the structure of FIG. 11a in an A-A direction.

FIG. 12a is a structural schematic view of a structure corresponding to an operation at block S3 in the method for transferring the liquid droplets of FIG. 10 in an embodiment.

FIG. 12b is a cross-sectional structural schematic view of the structure of FIG. 12a in a D-D direction.

FIG. 13a is a structural schematic view of a structure corresponding to an operation at block S4 in the method for transferring the liquid droplets of FIG. 10 in another embodiment.

FIG. 13b is a cross-sectional structural schematic view of the structure of FIG. 13a in a E-E direction.

FIG. 14 is a structural schematic view of a structure corresponding to first execution of an operation at block S3 in the method for transferring the liquid droplets of FIG. 10 in another embodiment.

FIG. 15 is a structural schematic view of a structure corresponding to first execution of an operation at block S4 in the method for transferring the liquid droplets of FIG. 10 in another embodiment.

FIG. 16 is a structural schematic view of a structure corresponding to second execution of the operation at block S4 in the method for transferring the liquid droplets of FIG. 10 in another embodiment.

FIG. 17 is a structural schematic view of a structure corresponding to first execution of an operation at block S3 in the method for transferring the liquid droplets of FIG. 10 in yet another embodiment.

FIG. 18 is a structural schematic view of a structure corresponding to first execution of an operation at block S4 in the method for transferring the liquid droplets of FIG. 10 in yet another embodiment.

FIG. 19 is a structural schematic view of a structure corresponding to second execution of the operation at block S4 in the method for transferring the liquid droplets of FIG. 10 in yet another embodiment.

FIG. 20 is a structural schematic view of a structure corresponding to third execution of the operation at block S4 in the method for transferring the liquid droplets of FIG. 10 in yet another embodiment.

FIG. 21 is a structural schematic view of a structure corresponding to an operation at block S1 in the method for transferring the liquid droplets of FIG. 10 in an embodiment.

FIG. 22 is a flowchart of the method for transferring the liquid droplets of FIG. 10 in an embodiment.

FIG. 23a is a structural schematic view of a structure corresponding to an operation at block S31 of FIG. 22 in an embodiment.

FIG. 23b is a cross-sectional structural schematic view of the structure of FIG. 23a in a F-F direction.

FIG. 24a is a structural schematic view of a structure corresponding to an operation at block S32 of FIG. 22 in an embodiment.

FIG. 24b is a cross-sectional structural schematic view of the structure of FIG. 24a in a H-H direction.

FIG. 25a is a structural schematic view of a structure corresponding to an operation at block S33 of FIG. 22 in an embodiment.

FIG. 25b is a cross-sectional structural schematic view of the structure of FIG. 25a in an I-I direction.

FIG. 25c is a cross-sectional structural schematic view of a structure of FIG. 25b after a liquid droplet is solidified.

FIG. 26 is a flowchart of the method for transferring the liquid droplets of FIG. 10 in another embodiment.

FIG. 27 is a structural schematic view of a structure corresponding to an operation at block S302 of FIG. 26 in an embodiment.

FIG. 28 is a flowchart of a second embodiment of a method for transferring the liquid droplets in the present disclosure.

FIG. 29 is a structural schematic view of a structure corresponding to an operation at block S4A in the method for transferring the liquid droplets of FIG. 28 in an embodiment.

FIG. 30 is a structural schematic view of a structure corresponding to an operation at block S5A in the method for transferring the liquid droplets of FIG. 28 in an embodiment.

FIG. 31 is a structural schematic view of a structure corresponding to an operation at block S5A in the method for transferring the liquid droplets of FIG. 28 in another embodiment.

FIG. 32 is a flowchart of a third embodiment of a method for transferring the liquid droplets in the present disclosure.

FIG. 33 is a structural schematic view of a structure corresponding to an operation at block S2B in the method for transferring the liquid droplets provided of FIG. 32 in an embodiment.

FIG. 34 is a structural schematic view of a structure corresponding to an operation at block S3B in the method for transferring the liquid droplets provided of FIG. 32 in an embodiment.

FIG. 35 is a structural schematic view of a structure corresponding to an operation at block S4B in the method for transferring the liquid droplets provided of FIG. 32 in an embodiment.

FIG. 36 is a structural schematic view of a structure corresponding to an operation at block S5B in the method for transferring the liquid droplets provided of FIG. 32 in an embodiment.

### DETAILED DESCRIPTION

The technical solutions in some embodiments of the present disclosure may be clearly and completely described in conjunction with accompanying drawings in some embodiments of the present disclosure. Obviously, the described embodiments are only a part of the embodiments of the present disclosure, and not all embodiments. Based on the embodiments in the present disclosure, all other embodiments obtained by those of ordinary skill in the art without creative effort are within the scope of the present disclosure.

The terms “first”, “second”, and “third” in the present disclosure are only configured to describe and cannot be understood as indicating or implying relative importance or implicitly indicating the quantity of technical features indicated. Therefore, features that are defined as “first”, “second”, and “third” may explicitly or implicitly include at least one of these features. In the description of the present disclosure, “multiple” means at least two, such as two, three, etc., unless otherwise expressly and specifically qualified. In addition, the terms “including”, “comprising”, and “having”, as well as any variations of the terms “including”, “comprising”, and “having”, are intended to cover non-exclusive inclusions. For example, a process, method, system, product, or apparatus that includes a series of operations or units is not limited to the listed operations or units, but optionally includes operations or units that are not listed, or optionally includes other operations or units that are inherent to these processes, methods, products, or apparatus.

The reference to “embodiment” in the present disclosure means that, specific features, structures, or characteristics described in conjunction with some embodiments may be included in at least one embodiment of the present disclosure. The phrase appearing in various positions in the specification does not necessarily refer to the same embodiment, nor is it an independent or alternative embodiment that is mutually exclusive with other embodiments. Those of ordinary skill in the art explicitly and implicitly understand that the embodiments described in the present disclosure can be combined with other embodiments.

The present disclosure mainly provides a microfluidic transfer substrate, a microfluidic transfer device, and a microfluidic transfer apparatus, so as to solve the problem of low film-forming efficiency of the light-emitting element layer of the organic light-emitting diode display panel in the related art.

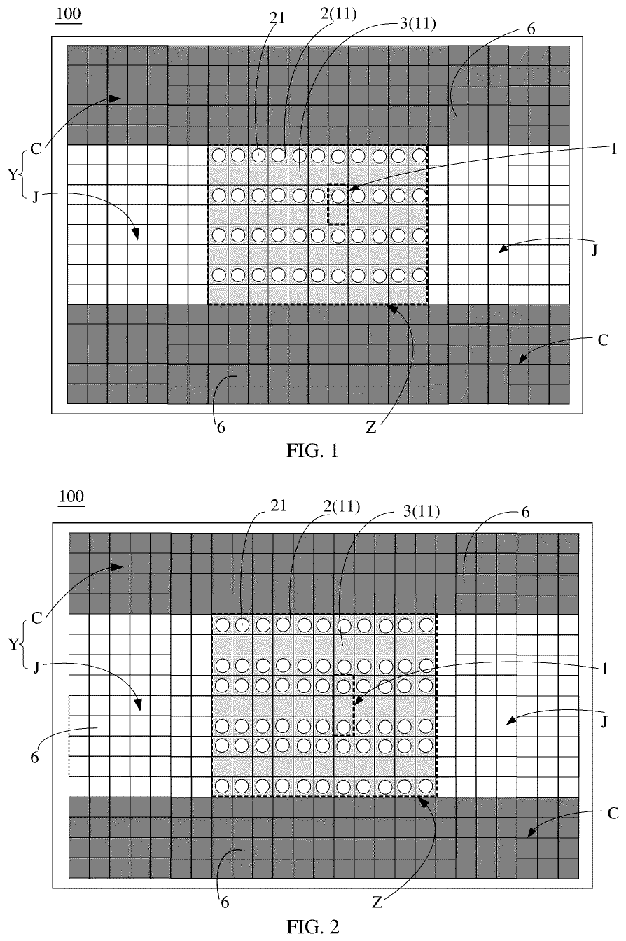

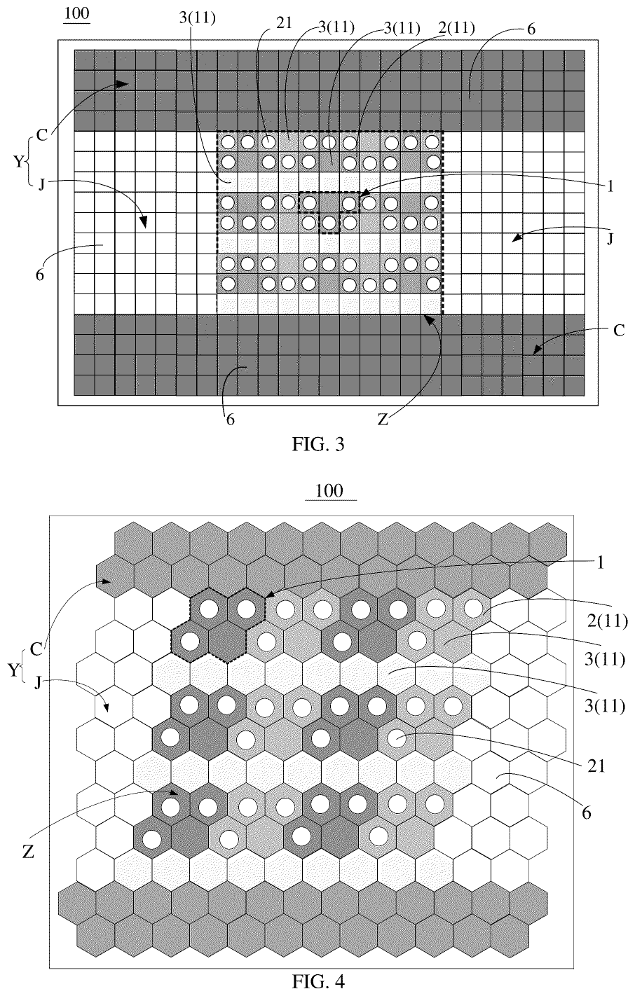

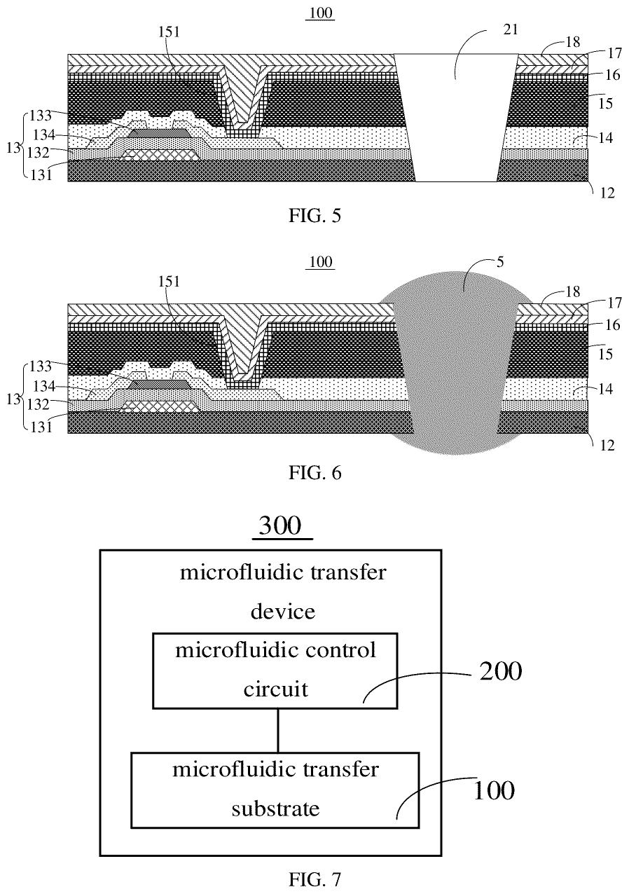

As illustrated in FIGS. 1 to 6, FIG. 1 is a structural schematic view of a first embodiment of a microfluidic transfer substrate in the present disclosure. FIG. 2 is a structural schematic view of a second embodiment of a microfluidic transfer substrate in the present disclosure. FIG. 3 is a structural schematic view of a third embodiment of a microfluidic transfer substrate in the present disclosure. FIG. 4 is a structural schematic view of a fourth embodiment of a microfluidic transfer substrate in the present disclosure. FIG. 5 is a cross-sectional structural schematic view of the microfluidic transfer substrate of FIG. 1. FIG. 6 is a cross-sectional structural schematic view of the microfluidic transfer substrate of FIG. 1 during transfer of a liquid droplet.

As illustrated in FIGS. 1 to 6, the present disclosure provides a microfluidic transfer substrate 100 including multiple first pixel units 11. Some first pixel units 11 serve as first microfluidic pixels 2 with through holes 21, while the other the first pixel units 11 serve as second microfluidic pixels 3 without through holes 21. Each first microfluidic pixel 2 is adjacent to at least one second microfluidic pixel 3.

By allowing the first microfluidic pixel 2 of the microfluidic transfer substrate 100 to define the through hole 21 and each first microfluidic pixel 2 adjacent to at least one second microfluidic pixel 3, it facilitates transfer of liquid droplets 5 using the microfluidic transfer substrate 100, so as to form light-emitting element layers on the driving backplane of an organic light-emitting diode display panel, thereby improving film-forming efficiency of the light-emitting element layer and solving the problem of low film-forming efficiency of the light-emitting element layer of the organic light-emitting diode display panel in the related art.

In some embodiments, the multiple first pixel units 11 of the microfluidic transfer substrate 100 are divided into multiple pixel groups 1, as illustrated in FIG. 1. In some embodiments, each pixel group 1 is composed of a first microfluidic pixel 2 and a second microfluidic pixel 3. As illustrated in FIG. 1, in some embodiments, the number of the first microfluidic pixels 2 and the number of the second microfluidic pixels 3 of the microfluidic transfer substrate 100 are the same, and the first microfluidic pixels 2 and the second microfluidic pixels 3 are disposed in a one-to-one correspondence.

In some embodiments, as illustrated in FIG. 1, the multiple first pixel units 11 of the microfluidic transfer substrate 100 are distributed in a two-dimensional array, and the first microfluidic pixel 2 and the second microfluidic pixel 3 of each pixel group 1 are located in the same column. In some embodiments, the first microfluidic pixel 2 and the second microfluidic pixel 3 of each pixel group 1 may also be located in the same row. Alternatively, the multiple first pixel units 11 of the microfluidic transfer substrate 100 may not be arranged in an array, and the first microfluidic pixel 2 and the second microfluidic pixel 3 of each pixel group 1 may not be located in the same row or column.

As illustrated in FIG. 2, in some embodiments, each pixel group 1 is composed of multiple first microfluidic pixels 2 and one second microfluidic pixel 3. As illustrated in FIG. 2, in some embodiments, each pixel group 1 is composed of two first microfluidic pixels 2 and one second microfluidic pixel 3. That is, two first microfluidic pixels 2 correspond to one second microfluidic pixel 3.

In some embodiments, as illustrated in FIG. 2, the multiple first pixel units 11 of the microfluidic transfer substrate 100 are distributed in the two-dimensional array. Two first microfluidic pixels 2 and one second microfluidic pixel 3 of each pixel group 1 are located in the same column, and one second microfluidic pixel 3 is located between the two first microfluidic pixels 2. In some embodiments, the two first microfluidic pixels 2 and one second microfluidic pixel 3 of each pixel group 1 may also be located in the same row. Alternatively, the multiple first pixel units 11 of the microfluidic transfer substrate 100 may not be arranged in the array, and the two first microfluidic pixels 2 and one second microfluidic pixel 3 of each pixel group 1 may not be located in the same row or column.

As illustrated in FIG. 1, in some embodiments, the multiple first pixel units 11 of the microfluidic transfer substrate 100 are arranged in the two-dimensional array. The odd-numbered rows of first pixel units 11 are all the first microfluidic pixels 2, while the even-numbered rows of first pixel units 11 are all the second microfluidic pixels 3 and serve as transport channels. The multiple first pixel units 11 are arranged in the two-dimensional array, and structures of the first pixel units 11 in the odd-numbered rows and the even-numbered rows are different. All the first pixel units 11 in the even-numbered rows are disposed as the second microfluidic pixels 3 to serve as the transport channels, which may facilitate transport of the liquid droplets 5 through the second microfluidic pixels 3 in the even-numbered rows. It facilitates the transfer of corresponding liquid droplet 5 on each second microfluidic pixel 3 in the even-numbered rows corresponding to each first microfluidic pixel 2 in the odd-numbered rows, thereby facilitating the transfer of the liquid droplets 5. In some embodiments, the first pixel units 11 in the odd-numbered rows may also be disposed as the second microfluidic pixels 3 and configured as the transport channels, while the first pixel units 11 in the even-numbered rows may be disposed as the first microfluidic pixels 2, facilitating the transport and the transfer of the liquid droplets 5.

As illustrated in FIG. 2, in some embodiments, the multiple first pixel units 11 of the microfluidic transfer substrate 100 are arranged in the two-dimensional array. For every three adjacent rows of first pixel units 11, the first pixel units 11 in the two outer rows are all the first microfluidic pixels 2, and the first pixel units 11 in the middle row are all the second microfluidic pixels 3 and serve as the transport channels. The multiple first pixel units 11 are arranged in the two-dimensional array, and the first pixel units 11 in the middle row of every three adjacent rows of first pixel units 11 are all the second microfluidic pixels 3 and serves as the transport channels. This configuration allows the second microfluidic pixels 3 in the middle row to transport the liquid droplets 5 to the first microfluidic pixels 2 in the two outer rows. Furthermore, it is also conducive to increasing the pixel density of the first microfluidic pixels 2 of the microfluidic transfer substrate 100, thereby increasing the pixel density of the organic light-emitting diode display panel.

As illustrated in FIG. 3, in some embodiments, the multiple first pixel units 11 are arranged in the two-dimensional array. For every three adjacent rows of first pixel units 11, the first pixel units 11 in one outer row are all the second microfluidic pixels 3 and serve as the transport channels. The other two rows of first pixel units 11 are divided into the multiple pixel groups 1 alternately arranged along a row direction. Each pixel group 1 is composed of three first microfluidic pixels 2 and one second microfluidic pixel 3, and the three first microfluidic pixels 2 of each pixel group 1 are adjacent to one second microfluidic pixel 3.

The multiple first pixel units 11 are arranged in the two-dimensional array. For every three adjacent rows of first pixel units 11, the first pixel units 11 in one outer row are all the second microfluidic pixels 3. The three first microfluidic pixels 2 of each pixel group 1 are adjacent to one second microfluidic pixel 3. The second microfluidic pixels 3 in one outer row serve as the transport channels. Therefore, the liquid droplets 5 may be transported to positions of the three first microfluidic pixels 2 of the pixel group 1 through the second microfluidic pixels 3 in the outer row and one second microfluidic pixel 3 of each pixel group 1, which facilitates the transport and the transfer of the liquid droplets 5. Furthermore, the first pixel units 11 of the other two rows are divided into the multiple pixel groups 1 alternately arranged along the row direction, which may further increase the density of the first microfluidic pixels 2 of the microfluidic transfer substrate 100, thereby increasing the pixel density of the organic light-emitting diode display panel.

As illustrated in FIG. 3, in some embodiments, the first pixel unit 11 is rectangular, and each of the three first microfluidic pixels 2 shares a side with the one second microfluidic pixel 3. A pattern formed by two adjacent pixel groups 1 is centrally symmetric. That is, each pixel group 1 has three first microfluidic pixels 2, and each of the three first microfluidic pixels 2 corresponds to one edge of the one second microfluidic pixel 3. In some embodiments, the multiple first pixel units 11 of the microfluidic transfer substrate 100 have the same shape, all of which are square shaped. Four first pixel units 11 of each pixel group 1 are distributed in two rows and three columns. The three first microfluidic pixels 2 are distributed in three columns, and the one second microfluidic pixel 3 is located in the middle column. Two first microfluidic pixels 2 and the one second microfluidic pixel 3 are distributed in the same row, and another first microfluidic pixel 2 is distributed in another row. The one second microfluidic pixel 3 of each pixel group 1 is surrounded by the three first microfluidic pixels 2 of the pixel group 1 and one second microfluidic pixel 3 located in the outer row. In some embodiments, the first pixel unit 11 may also be disposed to any shape, such as a rectangle, a circle, or a diamond, etc., as long as the liquid droplets 5 may be transported from the second microfluidic pixels 3 in the outer row to the positions of the first microfluidic pixels 2 of the pixel groups 1 in the other two rows.

As illustrated in FIG. 4, in some embodiments, the multiple first pixel units 11 of the microfluidic transfer substrate 100 are arranged in a hexagonal close-packed distribution, and each first pixel unit 11 is a circle or a regular hexagon, as illustrated in FIG. 4. In some embodiments, each first pixel unit 11 is a regular hexagon. For every three adjacent rows of first pixel units 11, the first pixel units 11 in the outer row are all the second microfluidic pixel 3 and serves as the transport channels. The first pixel units 11 in the other two rows are divided into the multiple pixel groups 1 alternately arranged along the row direction. Each pixel group 1 is composed of three first microfluidic pixels 2 and one second microfluidic pixel 3, and the three first microfluidic pixels 2 and the one second microfluidic pixel 3 are arranged in two rows and two columns with a staggered configuration. The three first microfluidic pixels 2 of each pixel group 1 are adjacent to the one second microfluidic pixel 3.

As illustrated in FIG. 4, in some embodiments, the first pixel unit 11 is the regular hexagon, and the other two rows of pixel groups 1 each include four first pixel units 11. The four first pixel units 11 are arranged in two rows and two columns with the staggered configuration. Each of the three first microfluidic pixels 2 of each pixel group 1 corresponds to one edge of the one second microfluidic pixel 3, and the three first microfluidic pixels 2 of each pixel group 1 correspond to three adjacent edges of the one second microfluidic pixel 3, respectively. That is, the three first microfluidic pixels 2 of each pixel group 1 are arranged around the one second microfluidic pixel 3, and the one second microfluidic pixel 3 of each pixel group 1 is adjacent to the second microfluidic pixel 3 located in the outer row.

The first pixel unit 11 is disposed as the circle or the regular hexagon, and the multiple first pixel units 11 are arranged in the hexagonal close-packed distribution, which may increase the density of the first microfluidic pixels 2 of the multiple first pixel units 11 of the microfluidic transfer substrate 100, thereby increasing the pixel density of the organic light-emitting diode display panel. Furthermore, the first pixel units 11 in the outer row are all the second microfluidic pixels 3 and serve as the transport channels. Therefore, the liquid droplets 5 may be transported to the positions of the three first microfluidic pixels 2 of the pixel group 1 through the second microfluidic pixels 3 in the outer row and the one second microfluidic pixel 3 of each pixel group 1, which facilitates the transport and the transfer of the liquid droplets 5.

As illustrated in FIGS. 1 to 4, in some embodiments, the microfluidic transfer substrate 100 has a transfer area Z and a liquid droplet input area Y located on a side of the transfer area Z. The multiple first pixel units 11 are disposed in the transfer area Z. The liquid droplet input area Y has multiple second pixel units 6, and the second pixel units 6 have the same structure as the second microfluidic pixels 3. The liquid droplet input area Y is communicated with the transport channels and configured for generating and transporting the liquid droplets 5 to the transfer area Z.

In some embodiments, as illustrated in FIGS. 1 to 4, the microfluidic transfer substrate 100 includes one transfer area Z and the liquid droplet input area Y. The liquid droplet input area Y includes two liquid droplet entry areas J and two liquid droplet generation areas C that are communicated. The two liquid droplet entry areas J are located on two opposite sides of the transfer area Z along the row direction and are communicated with the transport channels in the transfer area Z. The two liquid droplet generation areas C are located on two opposite sides of the transfer area Z and the liquid droplet entry areas J along a column direction. The liquid droplet generation areas C are configured to generate and transport the liquid droplets 5 to the liquid droplet entry areas J. The liquid droplet entry areas J are communicated with the transport channels and are configured to transport the liquid droplets 5 to the transfer area Z. That is, the liquid droplet entering areas J are only configured to transport the liquid droplets 5 to the transfer area Z, without generating the liquid droplets 5.

In some embodiments, both the liquid droplet entry areas J and the liquid droplet generation areas C have the multiple second pixel units 6, and the second pixel units 6 have the same structure as the second microfluidic pixels 3. The multiple second pixel units 6 in the liquid droplet generation areas C are communicated with the multiple second pixel units 6 in the liquid droplet entry areas J, and the multiple second pixel units 6 in the liquid droplet entry areas J are communicated with the transport channels of the transfer area Z. The liquid droplet generation areas C generate and transports the liquid droplets 5 to the liquid droplet entry areas J. The liquid droplets 5 are transported to the positions of the first microfluidic pixels 2 in the transfer area Z through the second pixel units 6 in the liquid droplet entry areas J and the transport channels in the transfer area Z.

In some embodiments, as illustrated in FIGS. 1 to 3, in some embodiments, the first pixel unit 11 in the transfer area Z is rectangular, and the multiple first pixel units 11 are arranged in the array. The liquid droplet input area Y including the liquid droplet entry areas J and the liquid droplet generation areas C has the multiple second pixel units 6, and the multiple second pixel units 6 are also rectangular. The multiple second pixel units 6 in the liquid droplet entry areas J and the liquid droplet generation areas C, and the multiple first pixel units 11 in the transfer area Z, are arranged together in the array. As illustrated in FIG. 4, in some embodiments, the first pixel units 11 in the transfer area Z are circular or hexagonal in shape, and the multiple first pixel units 11 are arranged in the hexagonal close-packed distribution. The multiple second pixel units 6 in the liquid droplet input area Y including the liquid droplet entry areas J and the liquid droplet generation areas C, are also circular or hexagonal in shape. The multiple second pixel units 6 in the liquid droplet entry areas J and the liquid droplet generation areas C are arranged in the hexagonal close-packed distribution together with the multiple first pixel units 11 in the transfer area Z.

In some embodiments, the microfluidic transfer substrate 100 may not have the liquid droplet generation area C, but only the liquid droplet entry area J. The liquid droplet entry area J may be located on one side of the transfer area Z or may be disposed around the transfer area Z, as long as the second pixel units 6 in the liquid droplet entry areas J are communicated with the transport channels in the liquid droplet input area Y, and the liquid droplets 5 may be transported to the transport channels in the transfer area Z. In some embodiments, other structural components may be configured to directly generate and transport the liquid droplets 5 to the liquid droplet entry area J. In some embodiments, the structural component may be a print head located above the microfluidic transfer substrate 100, and the liquid droplets 5 are directly dropped to the liquid droplet entry area J in the microfluidic transfer substrate 100, so that the liquid droplets 5 may be transported from the liquid droplet entry area J to the transport channels in the transfer area Z. Alternatively, the microfluidic transfer substrate 100 may not have the liquid droplet entry area J, but only the liquid droplet generation area C. The liquid droplet generation area C is disposed around the transfer area Z, so as to directly generate and transport the liquid droplets 5 to the transport channels in the transfer area Z. Alternatively, the microfluidic transfer substrate 100 may not have the liquid droplet generation area C and the liquid droplet entry area J. Instead, other structural components may be configured to directly generate and transport the liquid droplets 5 to the transport channels in the transfer area Z, which may be designed according to needs.

As illustrated in FIGS. 5 and 6, in some embodiments, the first pixel unit 11 includes a substrate 12, a thin film transistor (TFT) 13, a first insulating layer 14, a planarization layer 15, a microfluidic electrode layer 16, a second insulating layer 17, and a hydrophobic layer 18 arranged in sequence. In some embodiments, the microfluidic electrode layer 16 is a transparent conductive layer. In some embodiments, the microfluidic electrode layer 16 may be an indium tin oxide (ITO) transparent conductive layer. In some embodiments, the through hole 21 sequentially penetrates through the substrate 12, the first insulation layer 14, the planarization layer 15, the microfluidic electrode layer 16, the second insulation layer 17, and the hydrophobic layer 18. The through hole 21 is arranged in a staggered manner with the thin film transistor 13, which facilitates the transfer of the liquid droplets 5 using the microfluidic transfer substrate 100, so that the liquid droplets 5 that are transported to the transfer area Z enter the through hole 21 and fall onto the driving backplane located on one side of the microfluidic transfer substrate 100 through the through holes 21, completing the transfer of the liquid droplets 5. In some embodiments, the microfluidic electrode layer 16 may also partially cover the sidewall of the through hole 21.

In some embodiments, as illustrated in FIGS. 5 and 6, the thin film transistor 13 is disposed on the substrate 12. The thin film transistor 13 includes a gate metal layer 131, a gate insulation layer 132, an active layer 133, and a source drain metal layer 134 stacked in sequence. The gate insulation layer 132 is disposed on a side of the gate metal layer 131 away from the substrate 12 and covers the gate metal layer 131 and the substrate 12. The active layer 133 is disposed at a position corresponding to the gate metal layer 131 and partially covers the gate insulation layer 132. The source drain metal layer 134 is disposed on a side of the active layer 133 away from the substrate 12 and covers a part of the active layer 133 and a part of the gate insulation layer 132. The source drain metal layer 134 includes a source electrode (not labeled in the figures) and a drain electrode (not labeled in the figures) arranged at intervals. A part of the active layer 133 is exposed at a position where the drain electrode and source electrode are spaced apart from each other. The first insulation layer 14 is located on a side of the source drain metal layer 134 away from the substrate 12 and covers the source drain metal layer 134, the active layer 133, and the gate insulation layer 132. The planarization layer 15, the microfluidic electrode layer 16, the second insulation layer 17, and the hydrophobic layer 18 are disposed on a surface of the first insulation layer 14 away from the substrate 12. The planarization layer 15 defines a via hole 151 spaced apart from the assembly groove 21, the via hole 151 sequentially penetrates through the planarization layer 15 and the first insulation layer 14 and expose a part of the source drain metal layer 134. The microfluidic electrode layer 16 covers the sidewalls of the via hole 151 and is in contact with the source drain metal layer 134.

In some embodiments, the microfluidic transfer substrate 100 may also be configured in other forms. The first pixel unit 11 may have any other shape, and the multiple first pixel units 11 may be randomly distributed, as long as each first microfluidic pixel 2 is adjacent to at least one second microfluidic pixel 3, so as to transfer the liquid droplet 5 through the second microfluidic pixel 3 into the through hole 21 of the first microfluidic pixel 2, which may be designed according to needs.

As illustrated in FIG. 7, FIG. 7 is a structural block view of a microfluidic transfer device in the present disclosure.

As illustrated in FIG. 7, the present disclosure further provides a microfluidic transfer device 300 including the microfluidic transfer substrate 100 and a microfluidic control circuit 200. The microfluidic transfer substrate 100 may be any one of the microfluidic transfer substrates 100 in the above embodiments. The microfluidic control circuit 200 is electrically connected to the microfluidic transfer substrate 100. The microfluidic control circuit 200 is configured to control the liquid droplet 5 on the second microfluidic pixel 3 of the microfluidic transfer substrate 100 to move into the through hole 21 of the first microfluidic pixel 2, so as to achieve the transport and the transfer of the liquid droplets 5, thereby facilitating the transfer of the liquid droplets 5 to the driving backplane 700 using the microfluidic transfer device 300 in the present disclosure.

In some embodiments, the microfluidic control circuit 200 is also configured to drive the movement of the liquid droplets 5 on the microfluidic transfer substrate 100, so that the liquid droplet 5 generated in the liquid droplet input area Y enters the transport channel in the transfer area Z through the second pixel unit 6 in the liquid droplet input area Y, and stay on the second microfluidic pixel 3 corresponding to the first microfluidic pixel 2, which facilitates further control of the movement of the liquid droplet 5 that stay on the second microfluidic pixel 3.

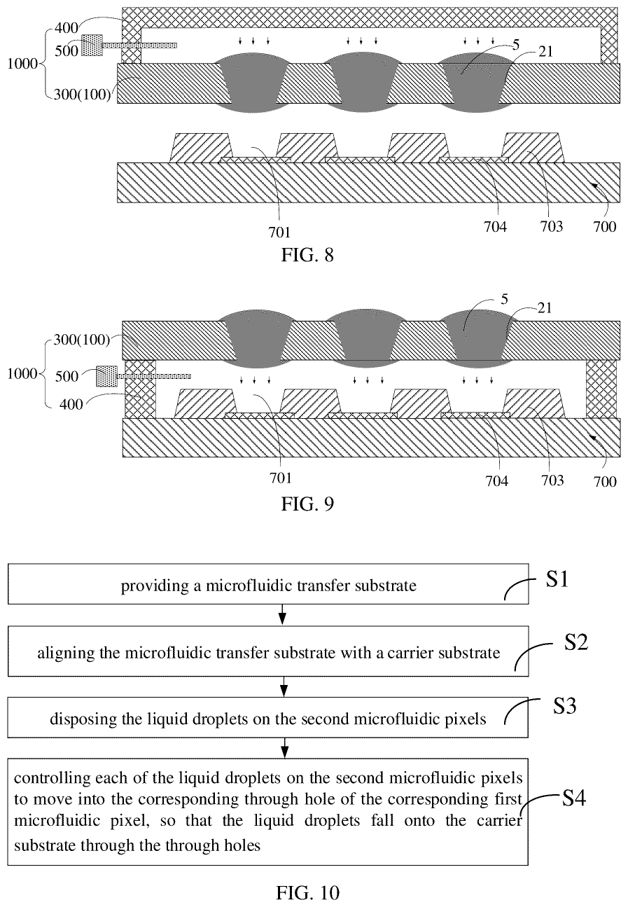

As illustrated in FIGS. 8 to 9, FIG. 8 is a structural schematic view of a microfluidic transfer apparatus in an embodiment of the present disclosure, and FIG. 9 is a structural schematic view of a microfluidic transfer apparatus in another embodiment of the present disclosure.

As illustrated in FIGS. 8 and 9, the present disclosure further provides a microfluidic transfer apparatus 1000 including the microfluidic transfer device 300, a sealing assembly 400, and an air pump 500. The microfluidic transfer device 300 may be the microfluidic transfer device 300 as described above. During the use of the microfluidic transfer device 300, the microfluidic transfer device 300 is aligned with the driving backplane 700. In some embodiments, the driving backplane 700 defines multiple grooves 701. In the process of using the microfluidic transfer device 300, the through holes 21 of the microfluidic transfer substrate 100 of the microfluidic transfer device 300 are aligned with the grooves 701 of the driving backplane 700, so that the liquid droplets 5 may fall into the grooves 701 of the driving backplane 700 through the through holes 21 of the microfluidic transfer substrate 100 in a case where the microfluidic transfer device 300 is used to transfer the liquid droplets 5 to the driving backplane 700.

As illustrated in FIG. 8, in some embodiments, the sealing assembly 400 is disposed on a side of the microfluidic transfer substrate 100 away from the driving backplane 700, and configured to seal a space on the side of the microfluidic transfer substrate 100 away from the driving backplane 700. The air pump 500 is configured to supply air to the space on the side of the microfluidic transfer substrate 100 away from the driving backplane 700, so as to increase an air pressure in the space on the side of the microfluidic transfer substrate 100 away from the driving backplane 700, and the space is sealed by the sealing assembly 400. The air pressure in the space on the side of the microfluidic transfer substrate 100 away from the driving backplane 700 may push the liquid droplets 5 in the through holes 21 of the microfluidic transfer substrate 100 out of the through holes 21, so that the liquid droplets 5 moving to the through holes 21 of the microfluidic transfer substrate 100 may fall more smoothly and efficiently into the grooves 701 of the driving backplane 700, thereby ensuring the transfer effect of the liquid droplets 5 and improve the transfer efficiency of liquid droplets 5.

As illustrated in FIG. 9, in some embodiments, the sealing assembly 400 is disposed between the microfluidic transfer substrate 100 and the driving backplane 700. The sealing assembly 400 is configured to seal the space between the microfluidic transfer substrate 100 and the driving backplane 700. The air pump 500 is configured to evacuate the space between the microfluidic transfer substrate 100 and the driving backplane 700, so as to reduce the air pressure in the space sealed by the sealing assembly 400 between the microfluidic transfer substrate 100 and the driving backplane 700, so that a negative pressure is formed in this space. The negative pressure in the space between the microfluidic transfer substrate 100 and the driving backplane 700 may draw the liquid droplets 5 in the through holes 21 of the microfluidic transfer substrate 100 out of the through holes 21, so that the liquid droplets 5 moving to the through holes 21 of the microfluidic transfer substrate 100 may fall more smoothly and efficiently into the grooves 701 of the driving backplane 700, thereby ensuring the transfer effect of the liquid droplets 5 and improving the transfer efficiency of liquid droplets 5.

In some embodiments, one sealing assembly 400 is disposed on the side of microfluidic transfer substrate 100 away from the driving backplane 700, and another sealing assembly 400 is disposed between microfluidic transfer substrate 100 and driving backplane 700. In addition, two air pumps 500 may be disposed, one air pump 500 is configured to supply air to the space on the side of the microfluidic transfer substrate 100 away from the driving backplane 700, while the other air pump 500 is configured to evacuate the space between the microfluidic transfer substrate 100 and the driving backplane 700. By simultaneously increasing the air pressure in the space on the side of the microfluidic transfer substrate 100 away from the driving backplane 700 and reducing the air pressure in the space between the microfluidic transfer substrate 100 and the driving backplane 700, the efficiency of the liquid droplets 5 in the through holes 21 of the microfluidic transfer substrate 100 dropping into the grooves 701 of the driver backplane 700 is further improved. It ensures that the liquid droplets 5 may fall smoothly and efficiently into the grooves 701 of the driving backplane 700, improving the transfer efficiency of liquid droplets 5. Alternatively, one sealing assembly 400 may be disposed on the side of the microfluidic transfer substrate 100 away from the driving backplane 700, another sealing assembly 400 may be disposed between the microfluidic transfer substrate 100 and the driving backplane 700, but only one air pump 500 may be disposed. Alternatively, the microfluidic transfer apparatus 1000 may not be provided with the sealing assembly 400 and the air pump 500, and the liquid droplets 5 may be accelerated to fall out of the through holes 21 through other means, such as electrostatic adsorption, etc. Therefore, the liquid droplets 5 in the through holes 21 fall out of the through holes 21 and fall into the grooves 701 of the driving backplane 700. It may be designed according to needs, and may not be limited in the present disclosure.

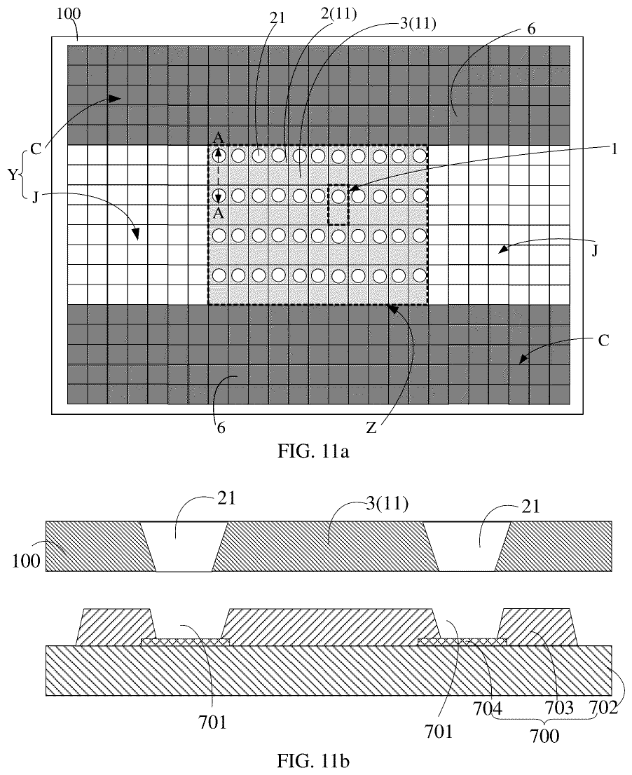

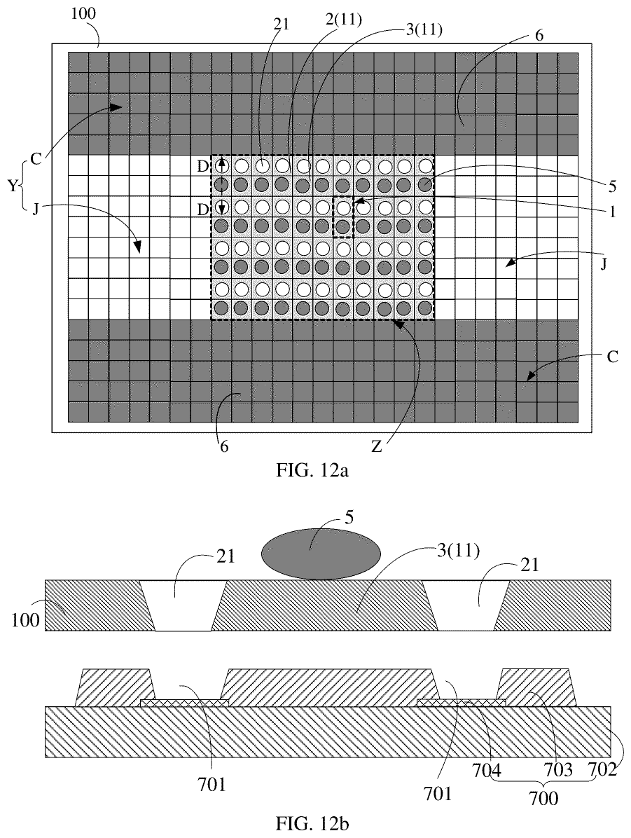

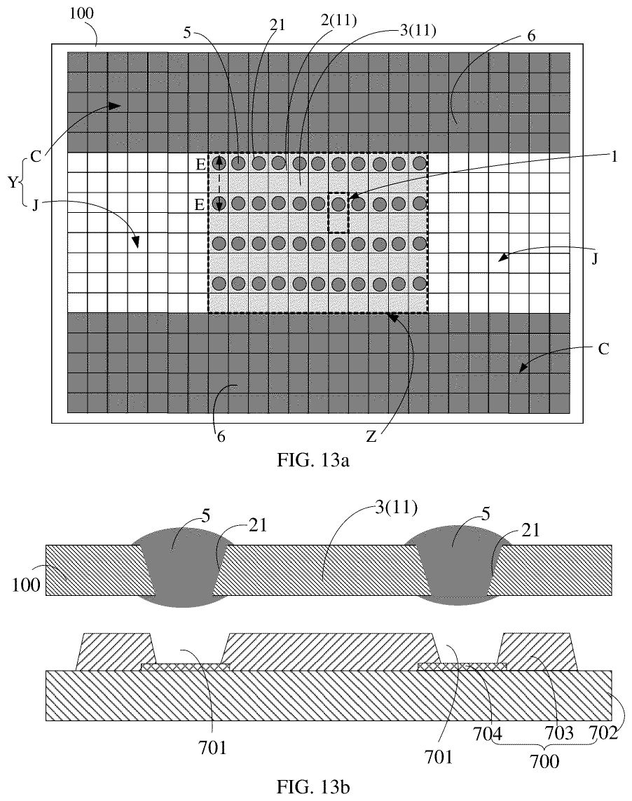

As illustrated in FIGS. 10 to 13b, FIG. 10 is a flowchart of a first embodiment of a method for transferring liquid droplets in the present disclosure. FIG. 11a is a structural schematic view of a structure corresponding to an operation at block S2 in the method for transferring the liquid droplets of FIG. 10. FIG. 11b is a cross-sectional structural schematic view of the structure of FIG. 11a in an A-A direction. FIG. 12a is a structural schematic view of a structure corresponding to an operation at block S3 in the method for transferring the liquid droplets of FIG. 10 in an embodiment. FIG. 12b is a cross-sectional structural schematic view of the structure of FIG. 12a in a D-D direction. FIG. 13a is a structural schematic view of a structure corresponding to an operation at block S4 in the method for transferring the liquid droplets of FIG. 10 in another embodiment. FIG. 13b is a cross-sectional structural schematic view of the structure of FIG. 13a in a E-E direction.

As illustrated in FIG. 10, the present disclosure provides a method for transferring the liquid droplets 5, which is a method for making a display panel, so as to achieve the transfer of the liquid droplets 5, thereby preparing the display panel. In some embodiments, the method for transferring the liquid droplets 5 includes the following operations.

At block S1, the method for transferring the liquid droplets 5 may include providing a microfluidic transfer substrate 100.

In some embodiments, the microfluidic transfer substrate 100 is first provided, the microfluidic transfer substrate 100 may be any one of the microfluidic transfer substrates 100 in the above embodiments, i.e., any one of the microfluidic transfer substrates 100 illustrated in FIGS. 1 to 4. In some embodiments, the microfluidic transfer substrate 100 includes the multiple first pixel units 11, some first pixel units 11 serve as the first microfluidic pixels 2 with the through holes 21, and the other first pixel units 11 serve as the second microfluidic pixels 3 without the through holes 21. Each first microfluidic pixel 2 is adjacent to at least one second microfluidic pixel 3.

At block S2, the method for transferring the liquid droplets 5 may include aligning the microfluidic transfer substrate 100 with a carrier substrate.

In some embodiments, the carrier substrate is provided, and the microfluidic transfer substrate 100 is aligned with the carrier substrate. In some embodiments, the microfluidic transfer substrate 100 has the same shape and size as the carrier substrate. The carrier substrate is located at the bottom of the microfluidic transfer substrate 100, and the liquid droplets 5 are located at the top of the microfluidic transfer substrate 100. That is, the liquid droplets 5 are located on the surface of the microfluidic transfer substrate 100 away from the carrier substrate. In some embodiments, the driving backplane 700 being the carrier substrate is taken as an example for illustration purposes. The driving backplane 700 defines the grooves 701. In some embodiments, the driving backplane 700 includes a base 702, a pixel definition layer 703 arranged on the base 702, and an anode 704 located in the space that is defined by the pixel definition layer 703. The groove 701 is formed by enclosing the pixel definition layer 703 and the anode 704 of the driving backplane 700. The microfluidic transfer substrate 100 is aligned with the carrier substrate, so that the through holes 21 of the microfluidic transfer substrate 100 are aligned with the grooves 701 of the carrier substrate, i.e., the driving backplane 700, so as to facilitate the subsequent transfer of the liquid droplets 5 in the grooves 701 of the driving backplane 700.

In some embodiments, the structure illustrated in FIGS. 11a and 11b may be obtained after the operation at block S2.

At block S3, the method for transferring the liquid droplets 5 may include disposing the liquid droplets 5 on the second microfluidic pixels 3.

In some embodiments, the liquid droplets 5 are disposed on the second microfluidic pixel 3 of the microfluidic transfer substrate 100. In some embodiments, taking the liquid droplet 5 containing an organic light-emitting material as an example. The liquid droplet 5 may also be a liquid droplet containing a quantum dot light-emitting material or a liquid droplet containing a color filter material. In some embodiments, the liquid droplets 5 may be generated through the liquid droplet input area Y of the microfluidic transfer substrate 100. The liquid droplets 5 are transported to the transport channels in the transfer area Z through the liquid droplet input area Y, and then transported to the second microfluidic pixels 3 through the transport channels. Alternatively, other structural components, such as the print head, may be configured to directly generate and transport the liquid droplets 5 to the second microfluidic pixels 3 in the transfer area Z.

In the actual process, the operation of disposing the liquid droplets 5 on the second microfluidic pixels 3 (as described in the operation at block S3) and the operation of aligning the microfluidic transfer substrate 100 with the carrier substrate (as described in the operation at block S2) do not have any distinction in the order of time. That is, the operation at block S3 and the operation at block S2 may be performed synchronously, or the operation at block S3 may be performed after the operation at block S2, or the operation at block S2 may be performed after the operation at block S3.

At block S4, the method for transferring the liquid droplets 5 may include controlling each of the liquid droplets 5 on the second microfluidic pixels 3 to move into the corresponding through hole 21 of the corresponding first microfluidic pixel 2, so that the liquid droplets 5 fall onto the carrier substrate through the through holes 21.

In some embodiments, the liquid droplets 5 on the second microfluidic pixels 3 of the microfluidic transfer substrate 100 are controlled to move into the through holes 21 of the first microfluidic pixels 2, so that the liquid droplets 5 fall onto the carrier substrate through the through holes 21, so as to complete the transfer of the liquid droplets 5. In some embodiments, taking the carrier substrate being the driving backplane 700 as an example, and the driving backplane 700 defines the grooves 701. In some embodiments, each groove 701 is formed by the pixel definition layer 703 and the anode 704 of the driving backplane 700. The liquid droplets 5 on the second microfluidic pixels 3 are controlled to move into the through holes 21 of the first microfluidic pixels 2, so that the liquid droplets 5 pass through the through holes 21 and fall into the grooves 701 formed by the pixel definition layer 703 and the anode 704 of the carrier substrate (i.e., the driving backplane 700), so as to complete the transfer of the liquid droplets 5.

In some embodiments, after controlling the liquid droplets 5 on the second microfluidic pixels 3 to move into the through holes 21 of the first microfluidic pixels 2, and allowing the liquid droplets 5 in the through holes 21 of the first microfluidic pixels 2 to pass through the through holes 21 and fall into the grooves 701 formed by the pixel definition layer 703 and the anode 704 of the carrier substrate, the liquid droplets 5 in the grooves 701 of the carrier substrate (i.e., the driving backplane 700) are dried. In some embodiments, photo curing or thermal curing may be configured to evaporate the solvent in the liquid droplets 5, so that each liquid droplet 5 is transformed into a solid film structure. In some embodiments, the liquid droplet 5 contains the organic light-emitting material, and the liquid droplet 5 in the groove 701 is dried to form the organic light-emitting layer 43 in the groove 701.

In some embodiments, the multiple first pixel units 11 of the microfluidic transfer substrate 100 are divided into the multiple pixel groups 1, each pixel group 1 is composed of one first microfluidic pixel 2 and one second microfluidic pixel 3 (as illustrated in FIG. 1). In the above method for transferring the liquid droplets 5, in the operation at block S3, one liquid droplet 5 may be first disposed on the second microfluidic pixel 3 of each pixel group 1. Then, in the operation at block S4, all liquid droplets 5 on the second microfluidic pixels 3 may be simultaneously driven, so that each liquid droplet moves into the corresponding through hole 21 of the first microfluidic pixel 2.

In some embodiments, the microfluidic transfer substrate 100 is as illustrated in FIG. 1. The operations S3 and S4 are performed only once. After the operation at block S3, the structure illustrated in FIGS. 12a and 12b may be obtained. After the operation at block S4, the structure illustrated in FIGS. 13a and 13b may be obtained.

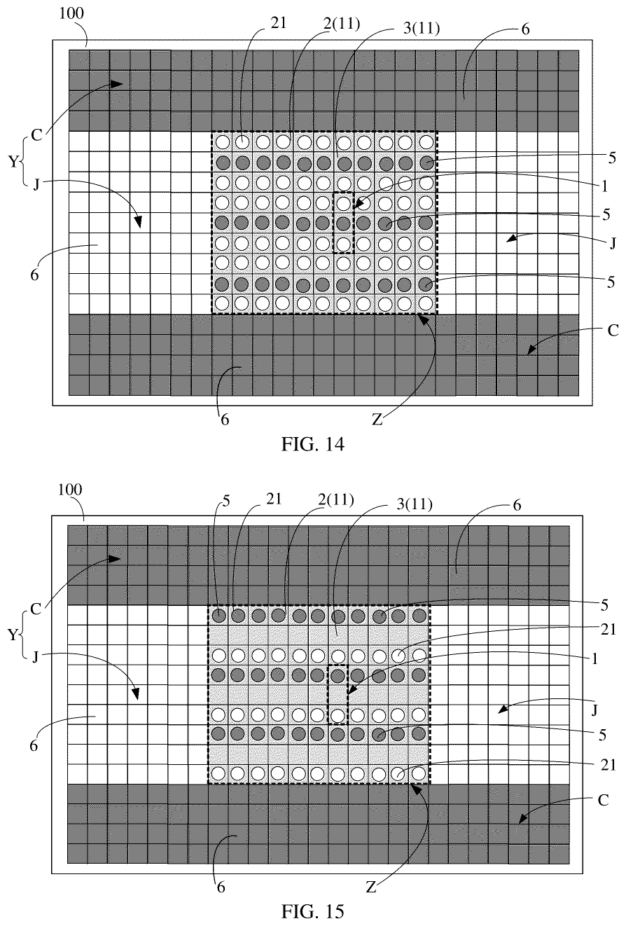

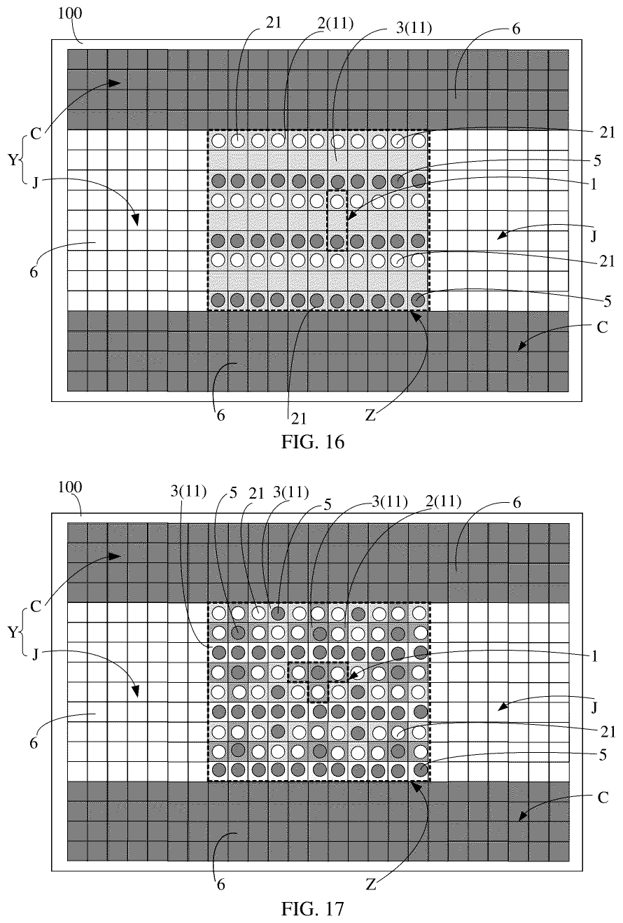

As illustrated in FIGS. 14 to 16, FIG. 14 is a structural schematic view of a structure corresponding to first execution of an operation at block S3 in the method for transferring the liquid droplets of FIG. 10 in another embodiment. FIG. 15 is a structural schematic view of a structure corresponding to first execution of an operation at block S4 in the method for transferring the liquid droplets of FIG. 10 in another embodiment. FIG. 16 is a structural schematic view of a structure corresponding to second execution of the operation at block S4 in the method for transferring the liquid droplets of FIG. 10 in another embodiment.

In some embodiments, the multiple first pixel units 11 of the microfluidic transfer substrate 100 are divided into the multiple pixel groups 1, each pixel group 1 is composed of multiple first microfluidic pixels 2 and one second microfluidic pixel 3 (as illustrated in FIGS. 2 to 4). In the above method for transferring the liquid droplets 5, the operation at block S3 and the operation at block S4 may be alternately repeated. In some embodiments, the above method for transferring the liquid droplets 5 may include: first disposing one liquid droplet 5 on the second microfluidic pixel 3 of each pixel group 1; then simultaneously driving each of all liquid droplets 5 on the second microfluidic pixels 3 to move into the through hole 21 of a first one of the first microfluidic pixels 2 of the multiple pixel groups 1; repeating the above operations and disposing the liquid droplet 5 in the through hole 21 of each first microfluidic pixel 2 of each pixel group 1.

In some embodiments, in the operation at block S3, one liquid droplet 5 may be disposed on the second microfluidic pixel 3 of each pixel group 1. Then, in the operation at block S4, each of all liquid droplets 5 on the second microfluidic pixels 3 may be simultaneously driven to move into the through hole 21 of the first one of the first microfluidic pixels 2 of the multiple pixel groups 1. The above operations are repeated, that is, the operation at block S3 and the operation at block S4 are repeated, so that the liquid droplet 5 is disposed in the through hole 21 of each first microfluidic pixel 2 of each pixel group 1. The operation at block S3 and the operation at block S4 are alternately repeated, so that the liquid droplet 5 is disposed in the through hole 21 of each first microfluidic pixel 2 of each pixel group 1.

In some embodiments, the microfluidic transfer substrate 100 is as illustrated in FIG. 2. Each pixel group 1 is composed of two first microfluidic pixels 2 and one second microfluidic pixel 3, and the operation at block S3 and the operation at block S4 need to be alternately repeated twice. After the first execution of the operation at block S3, the structure illustrated in FIG. 14 may be obtained. After the first execution of the operation at block S4, the structure illustrated in FIG. 15 may be obtained. After the first execution of the operation at block S4, the liquid droplet 5 in the through hole 21 of the first one of the first microfluidic pixels 2 of the pixel group 1 has already dropped onto the corresponding position of the carrier substrate (i.e. the driving backplane 700). There is no liquid droplet 5 in the through hole 21 of the first one of the first microfluidic pixels 2. Therefore, the structure obtained after the second execution of the operation at block S3 is the same as the structure corresponding to the first execution of the operation at block S3. During the second execution of the operation at block S4, each of all liquid droplets 5 on the second microfluidic pixels 3 is driven to move into the through hole 21 of a second one of the first microfluidic pixels 2 of the multiple pixel groups 1, so that the structure illustrated in FIG. 16 may be obtained.

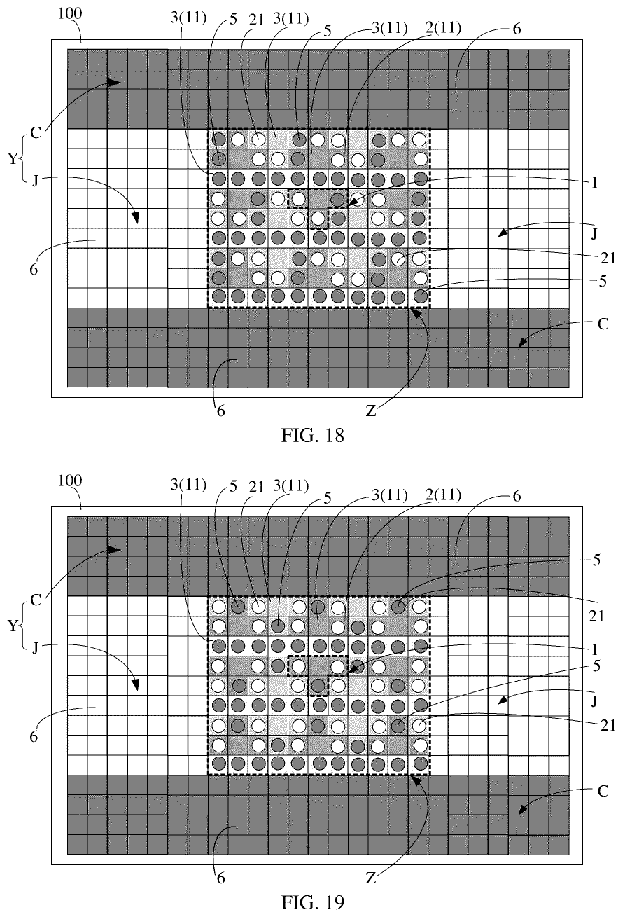

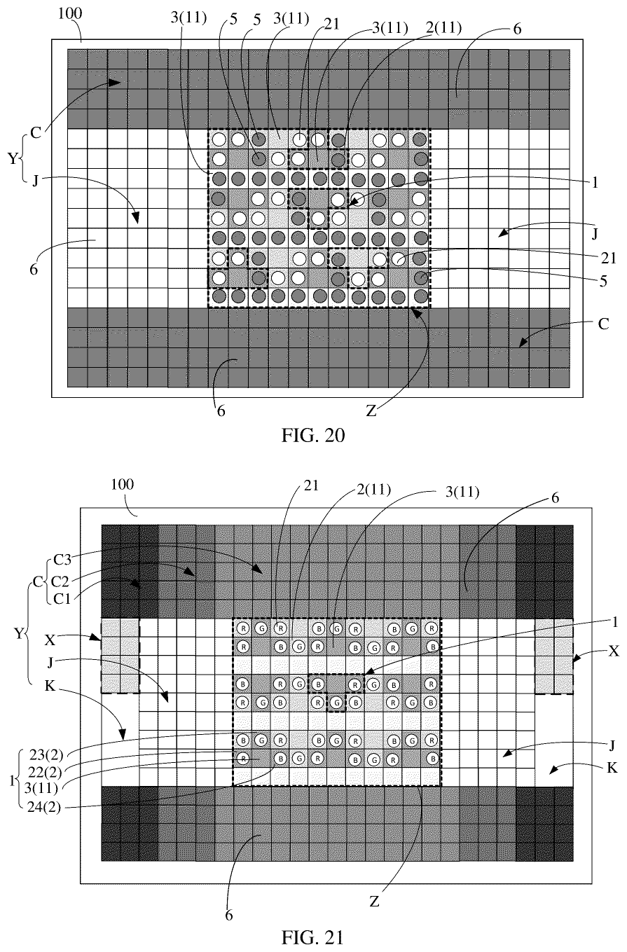

As illustrated in FIGS. 17 to 20, FIG. 17 is a structural schematic view of a structure corresponding to first execution of an operation at block S3 in the method for transferring the liquid droplets of FIG. 10 in yet another embodiment. FIG. 18 is a structural schematic view of a structure corresponding to first execution of an operation at block S4 in the method for transferring the liquid droplets of FIG. 10 in yet another embodiment. FIG. 19 is a structural schematic view of a structure corresponding to second execution of the operation at block S4 in the method for transferring the liquid droplets of FIG. 10 in yet another embodiment. FIG. 20 is a structural schematic view of a structure corresponding to third execution of the operation at block S4 in the method for transferring the liquid droplets of FIG. 10 in yet another embodiment.

In some embodiments, the microfluidic transfer substrate 100 is as illustrated in FIG. 3, and each pixel group 1 is composed of three first microfluidic pixels 2 and one second microfluidic pixel 3. The operation at block S3 and the operation at block S4 need to be alternately repeated three times. After the first execution of the operation at block S3, the structure illustrated in FIG. 17 may be obtained. In some embodiments, the first pixel units 11 in the outer row of every three adjacent rows of first pixel units 11 serve as the transport channels. In some embodiments, in the operation at block S3, the liquid droplets 5 are also disposed on the second microfluidic pixels 3 of the transport channels. Therefore, after the operation at block S4 of moving the liquid droplet 5 on the second microfluidic pixel 3 of the pixel group 1 to the through hole 21 of the first one of the first microfluidic pixels 2 of the pixel group 1, the liquid droplet 5 on the second microfluidic pixel 3 of the transport channel is immediately moved and supplemented to the second microfluidic pixel 3 of the pixel group 1, which is conducive to improving the transfer efficiency of the liquid droplets 5. In some embodiments, in the operation at block S3, the liquid droplet 5 may also be disposed only on the second microfluidic pixel 3 of the pixel group 1, and liquid droplets 5 may not disposed on the second microfluidic pixels 3 that are serve as the transport channels on the outer row of every three adjacent rows of first pixel units 11. After the first execution of the operation at block S4, the structure illustrated in FIG. 18 may be obtained. Similarly, after the first execution of the operation at block S4, the liquid droplet 5 in the through hole 21 of the first one of the first microfluidic pixels 2 of the pixel group 1 has already dropped onto the corresponding position of the carrier substrate (i.e. the driving backplane 700). There is no liquid droplet 5 in the through hole 21 of the first one of the first microfluidic pixels 2. Therefore, the structure obtained after the second execution of the operation at block S3 is the same as the structure corresponding to the first execution of the operation at block S3. During the second execution of the operation at block S4, each of all liquid droplets 5 on the second microfluidic pixels 3 is driven to move into the through hole 21 of the second one of the first microfluidic pixels 2 of the multiple pixel groups 1, so that the structure illustrated in FIG. 19 may be obtained. Similarly, the structure obtained after the third execution of the operation at block S3 is the same as the structure corresponding to the first execution of the operation at block S3. During the third execution of the operation at block S4, each of all liquid droplets 5 on the second microfluidic pixels 3 is driven to move into the through hole 21 of a third one of the first microfluidic pixels 2 of the multiple pixel groups 1, so that the structure illustrated in FIG. 20 may be obtained.

In some embodiments, the microfluidic transfer substrate 100 is illustrated in FIG. 4, and each pixel group 1 is composed of three first microfluidic pixels 2 and one second microfluidic pixel 3. The operation at block S3 and the operation at block S4 need to be alternately repeated three times. The structures corresponding to the third execution of the operation at block S3 and the operation at block S4 may refer to the structures illustrated in FIGS. 17 to 20, which may not be repeated here.

In some embodiments, after the operation of controlling each of the liquid droplets 5 on the second microfluidic pixels 3 to move into the corresponding through holes 21 of the corresponding first microfluidic pixel 2, so that the liquid droplets 5 fall onto the carrier substrate through the through holes 21, as described in operation at block S4, the method for transferring the liquid droplets 5 may further include: causing the liquid droplets 5 to detach from the through holes 21 by the air pressure.

In some embodiments, as illustrated in FIG. 8 or FIG. 9, the microfluidic transfer substrate 100 is spaced apart from the driving backplane 700. As illustrated in FIG. 8, in some embodiments, the sealing assembly 400 is disposed on the side of the microfluidic transfer substrate 100 away from the driving backplane 700. The sealing assembly 400 seals the space on the side of the microfluidic transfer substrate 100 away from the driving backplane 700, and is configured to supply air to the space on the side of the microfluidic transfer substrate 100 away from the driving backplane 700 through the air pump 500. That is, the top of the microfluidic transfer substrate 100 is inflated to increase the air pressure in the space on the side of the microfluidic transfer substrate 100 away from the driving backplane 700, and the space is sealed by the sealing assembly 400. The liquid droplets 5 in the through holes 21 of the microfluidic transfer substrate 100 are pushed out of the through holes 21 by the air pressure in the space on the side of the microfluidic transfer substrate 100 away from the driving backplane 700, so that the liquid droplets 5 fall out of the through holes 21, thereby improving the transfer efficiency of the liquid droplets 5.

As illustrated in FIG. 9, in some embodiments, the sealing assembly 400 is disposed between the microfluidic transfer substrate 100 and the driving backplane 700. The sealing assembly 400 seals the space between the microfluidic transfer substrate 100 and the driving backplane 700, and the space between the microfluidic transfer substrate 100 and the driving backplane 700 is evacuated by the air pump 500. That is, the bottom of the microfluidic transfer substrate 100 is evacuated, so as to reduce the air pressure in the space sealed by the sealing assembly 400 between the microfluidic transfer substrate 100 and the driving backplane 700, so that the negative pressure is formed in this space. The liquid droplets 5 in the through holes 21 of the microfluidic transfer substrate 100 are drawn out of the through holes 21 by the negative pressure in the space between the microfluidic transfer substrate 100 and the driving backplane 700, so that the liquid droplets 5 falls out of the through holes 21, improving the transfer efficiency of the liquid droplets 5.

In some embodiments, one sealing assembly 400 may also be disposed on the side of the microfluidic transfer substrate 100 away from the driving backplane 700, and another sealing assembly 400 is disposed between the microfluidic transfer substrate 100 and the driving backplane 700. Furthermore, the top of the microfluidic transfer substrate 100 may be inflated and the bottom of the microfluidic transfer substrate 100 may be evacuated, so that the liquid droplets 5 may be detached from the through holes 21 through the air pressure, thereby improving the transfer efficiency of the liquid droplets 5.

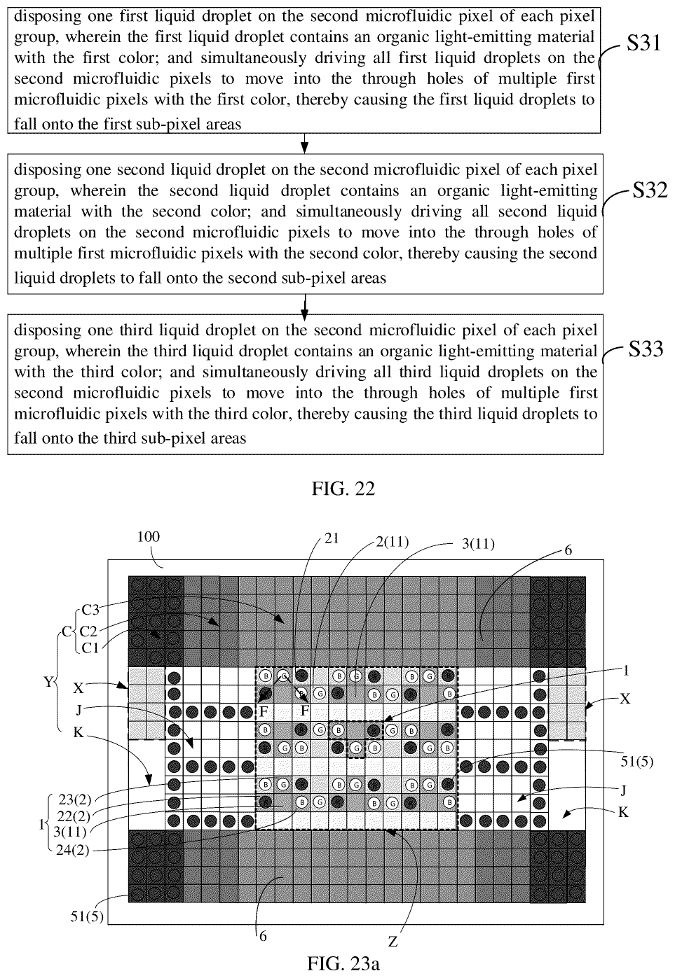

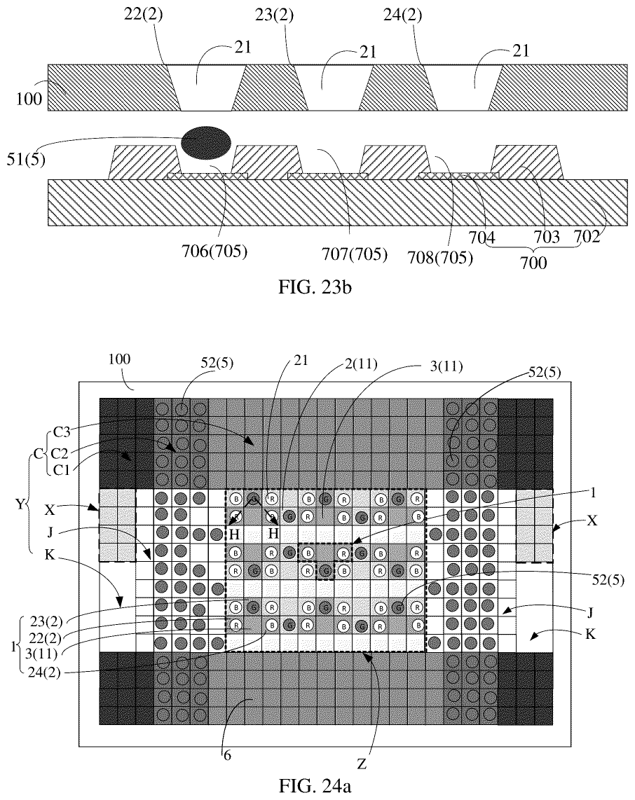

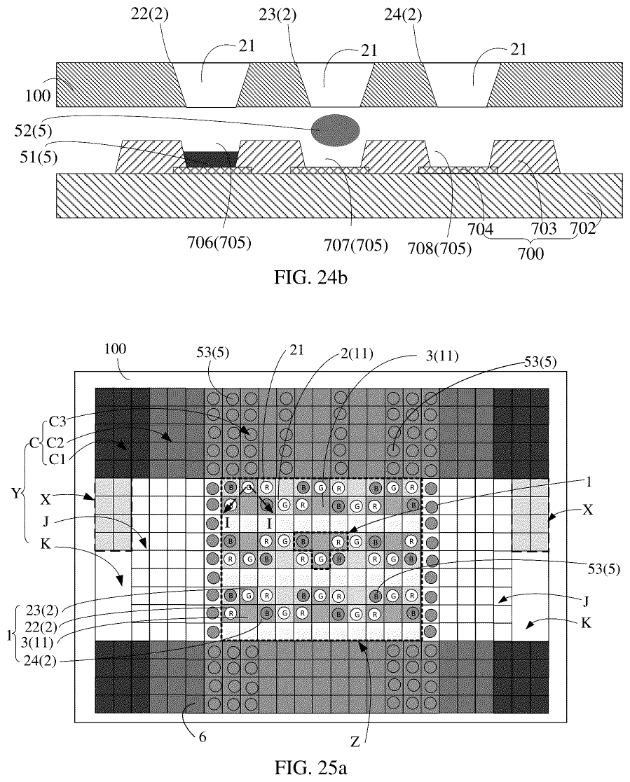

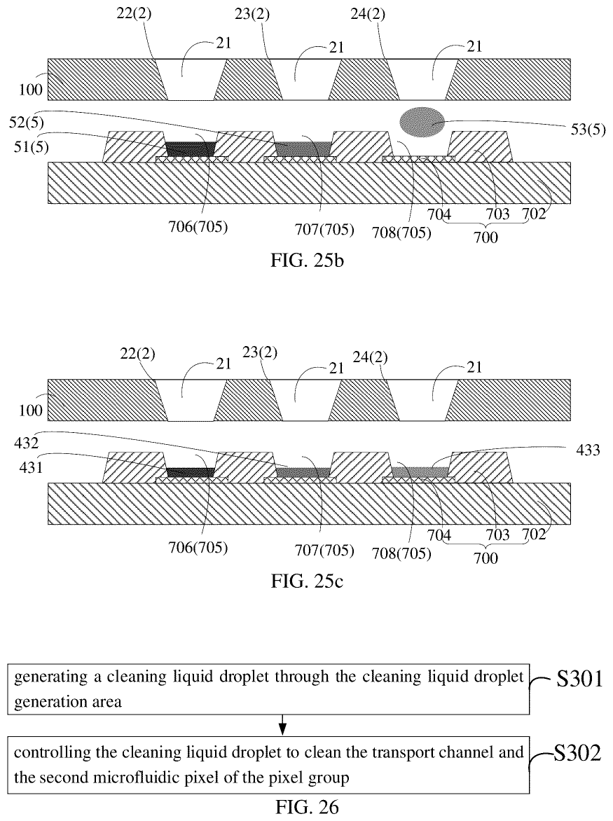

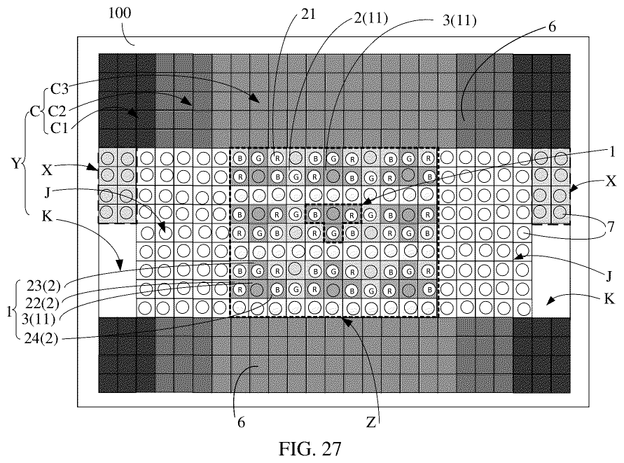

As illustrated in FIGS. 21 to 27, FIG. 21 is a structural schematic view of a structure corresponding to an operation at block S1 in the method for transferring the liquid droplets of FIG. 10 in an embodiment. FIG. 22 is a flowchart of the method for transferring the liquid droplets of FIG. 10 in an embodiment. FIG. 23a is a structural schematic view of a structure corresponding to an operation at block S31 of FIG. 22 in an embodiment. FIG. 23b is a cross-sectional structural schematic view of the structure of FIG. 23a in a F-F direction. FIG. 24a is a structural schematic view of a structure corresponding to an operation at block S32 of FIG. 22 in an embodiment. FIG. 24b is a cross-sectional structural schematic view of the structure of FIG. 24a in a H-H direction. FIG. 25a is a structural schematic view of a structure corresponding to an operation at block S33 of FIG. 22 in an embodiment. FIG. 25b is a cross-sectional structural schematic view of the structure of FIG. 25a in an I-I direction. FIG. 25c is a cross-sectional structural schematic view of a structure of FIG. 25b after a liquid droplet is solidified. FIG. 26 is a flowchart of the method for transferring the liquid droplets of FIG. 10 in another embodiment. FIG. 27 is a structural schematic view of a structure corresponding to an operation at block S302 of FIG. 26 in an embodiment.

In some embodiments, the carrier substrate is the driving backplane 700 including multiple sub-pixel areas 705. The multiple sub-pixel areas 705 includes multiple first sub-pixel areas 706, multiple second sub-pixel areas 707, and multiple third sub-pixel areas 708. The multiple first pixel units 11 of the microfluidic transfer substrate 100 are divided into the multiple pixel groups 1, and each pixel group 1 is composed of three first microfluidic pixels 2 and one second microfluidic pixel 3 (as illustrated in FIGS. 3, 4, and 21). In some embodiments, as illustrated in FIG. 21, the three first microfluidic pixels 2 are, respectively, a first microfluidic pixel with a first color 22, a first microfluidic pixel with a second color 23, and a first microfluidic pixel with a third color 24.

In the above method for transferring the liquid droplets 5, the operation at block S3 and the operation at block S4 may be alternately performed, as illustrated in FIG. 22. The method for transferring the liquid droplets 5 may include the following operations.

At block S31, the method for transferring the liquid droplets 5 may include disposing one first liquid droplet 51 on the second microfluidic pixel 3 of each pixel group 1, wherein the first liquid droplet 51 contains an organic light-emitting material with the first color; and simultaneously driving all first liquid droplets 51 on the second microfluidic pixels 3 to move into the through holes 21 of multiple first microfluidic pixels with the first color 22, thereby causing the first liquid droplets 51 to fall onto the first sub-pixel areas 706.

In some embodiments, one first liquid droplet 51 is disposed on the second microfluidic pixel 3 of each pixel group 1 of the microfluidic transfer substrate 100. The first liquid droplet 51 contains the organic light-emitting material with the first color, and all first liquid droplets 51 on the second microfluidic pixels 3 are driven to move into the through holes 21 of the multiple first microfluidic pixels with the first color 22, so that the first liquid droplets 51 fall onto the first sub-pixel areas 706.

In some embodiments, as illustrated in FIG. 21, the microfluidic transfer substrate 100 has the transfer area Z and the liquid droplet input area Y located on one side of the transfer area Z. The multiple first pixel units 11 are disposed in the transfer area Z. The liquid droplet input area Y includes the liquid droplet entry area J, a first liquid droplet generation area C1, a second liquid droplet generation area C2, and a third liquid droplet generation area C3. The first liquid droplet generation area C1, the second liquid droplet generation area C2, and the third liquid droplet generation area C3 are respectively communicated with the liquid droplet entry area J. The transfer area Z also has the transport channels including the multiple second microfluidic pixels 3. Each pixel group 1 is communicated with the liquid droplet entering area J through the transport channel. The operation of disposing one first liquid droplet 51 on the second microfluidic pixel 3 of each pixel group 1, as described in the operation at block S31, includes: generating the first liquid droplet 51 through the first liquid droplet generation area C1, and moving the first liquid droplet 51 to the second microfluidic pixel 3 of the pixel group 1 through the liquid droplet entry area J and transport channel.

In some embodiments, the first liquid droplet generation area C1 is configured to generate the first liquid droplets 51 containing the organic light-emitting materials with the first color. The first liquid droplet generation area C1 is communicated with the liquid droplet entry area J, and the first liquid droplet 51 is moved to the second microfluidic pixel 3 of each pixel group 1 through the liquid droplet entry area J and the transport channel in the transfer area Z.

In some embodiments, after the operation at block S31, the structure illustrated in FIGS. 23a and 23b may be obtained.

At block S32, the method for transferring the liquid droplets 5 may include disposing one second liquid droplet 52 on the second microfluidic pixel 3 of each pixel group 1, wherein the second liquid droplet 52 contains an organic light-emitting material with the second color; and simultaneously driving all second liquid droplets 52 on the second microfluidic pixels 3 to move into the through holes 21 of multiple first microfluidic pixels with the second color 23, thereby causing the second liquid droplets 52 to fall onto the second sub-pixel areas 707.

In some embodiments, after moving the first liquid droplets 51 into the through holes 21 of the multiple first microfluidic pixels with the first color 22 and dropping the first liquid droplets 51 onto the first sub-pixel areas 706, one second liquid droplet 52 is disposed on the second microfluidic pixel 3 of each pixel group 1, and the second liquid droplet 52 contains the organic light-emitting material with the second color. By simultaneously driving all second liquid droplets 52 on the second microfluidic pixels 3 to move into the through holes 21 of the multiple first microfluidic pixels with the second color 23, the second liquid droplets 52 fall onto the second sub-pixel areas 707.

Similarly, in some embodiments, the operation at block S32 of disposing one second liquid droplet 52 on the second microfluidic pixel 3 of each pixel group 1, includes: generating the second liquid droplet 52 through the second liquid droplet generation area C2, and moving the second liquid droplet 52 to the second microfluidic pixel 3 of the pixel group 1 through the liquid droplet entry area J and the transport channel.

In some embodiments, the second liquid droplet generation area C2 is configured to generate the second liquid droplet 52 containing an organic light-emitting material with the second color. The second liquid droplet generation area C2 is communicated with the liquid droplet entry area J, and the second liquid droplet 52 is moved to the second microfluidic pixel 3 of each pixel group 1 through the liquid droplet entry area J and the transport channel in the transfer area Z.

In some embodiments, after the operation at block S32, the structure illustrated in FIGS. 24a and 24b may be obtained.

At block S33, the method for transferring the liquid droplets 5 may include disposing one third liquid droplet 53 on the second microfluidic pixel 3 of each pixel group 1, wherein the third liquid droplet 53 contains an organic light-emitting material with the third color; and simultaneously driving all third liquid droplets 53 on the second microfluidic pixels 3 to move into the through holes 21 of multiple first microfluidic pixels with the third color 24, thereby causing the third liquid droplets 53 to fall onto the third sub-pixel areas 708.

After moving the second liquid droplets 52 into the through holes 21 of the multiple first microfluidic pixels with the second color 23, and dropping the second liquid droplets 52 onto the first sub-pixel areas 706, one third liquid droplet 53 is disposed on the second microfluidic pixel 3 of each pixel group 1. The third liquid droplets 53 contains the organic light-emitting material with the third color. By simultaneously driving all the third liquid droplets 53 on the second microfluidic pixels 3 to move into the through holes 21 of the multiple first microfluidic pixels with the third color 24, the third liquid droplets 53 fall onto the third sub-pixel areas 708.

Similarly, in some embodiments, the operation of disposing one third liquid droplet 53 on the second microfluidic pixel 3 of each pixel group 1, as described in operation at block S33, includes: generating the third liquid droplet 53 through the third liquid droplet generation area C3, and moving the third liquid droplet 53 onto the second microfluidic pixel 3 of the pixel group 1 through the liquid droplet entry area J and the transport channel.

In some embodiments, the third liquid droplet generation area C3 is configured to generate the third liquid droplet 53 containing an organic light-emitting material with the third color. The third liquid droplet generation area C3 is communicated with the liquid droplet entry area J, and the third liquid droplet 53 is moved to the second microfluidic pixel 3 of each pixel group 1 through the liquid droplet entry area J and the transport channel in the transfer area Z.

In some embodiments, after the operation at block S33, the structure illustrated in FIGS. 25a and 25b may be obtained.

In some embodiments, after the first liquid droplet 51 fall onto the first sub-pixel area 706, the solvent in the first liquid droplet 51 may be directly removed to form an organic light-emitting layer with the first color 431 in the first sub-pixel area 706. After the second liquid droplet 52 falls into the second sub-pixel area 707, the solvent in the second liquid droplet 52 may be directly removed to form an organic light-emitting layer with the second color 432 in the second sub-pixel area 707. After the third liquid droplet 53 falls into the third sub-pixel area 708, the solvent in the third liquid droplet 53 may be directly removed to form an organic light-emitting layer with the third color 433 in the third sub-pixel area 708. Alternatively, after the first liquid droplet 51 falls into the first sub-pixel area 706, the second liquid droplet 52 falls into the second sub-pixel area 707, and the third liquid droplet 53 falls into the third sub-pixel area 708, the first liquid droplet 51, the second liquid droplet 52, and the third liquid droplet 53 may be uniformly dried using light curing or heat curing. Therefore, the solvent of the first liquid droplet 51, the solvent of the second liquid droplet 52, and the solvent of the third liquid droplet 53 are respectively removed, so that the organic light-emitting layer with the first color 431, the organic light-emitting layer with the second color 432, and the organic light-emitting layer with the third color 433 (as illustrated in FIG. 5c) are respectively formed, which may be designed according to needs.

In some embodiments, as illustrated in FIG. 21, the liquid droplet input area Y further includes a cleaning liquid droplet generation area X communicated with the liquid droplet entry area J. The cleaning liquid droplet generation area X is located on one side of the liquid droplet entry area J, as illustrated in FIG. 26. Before the operation of moving the liquid droplets 5 to the second microfluidic pixels 3 of the pixel groups 1 through the liquid droplet entry area J and the transport channels in the operation at block S31, the operation at block S32, and the operation at block S33, the method for transferring the liquid droplets 5 may include the following operations.

At block S301, the method for transferring the liquid droplets 5 may include generating a cleaning liquid droplet 7 through the cleaning liquid droplet generation area X.

In some embodiments, the cleaning liquid droplet 7 is generated through the cleaning liquid droplet generation area X, the cleaning liquid droplet 7 does not contain the functional layer material and is only configured for cleaning the microfluidic transfer substrate 100.

At block S302, the method for transferring the liquid droplets 5 may include controlling the cleaning liquid droplet 7 to clean the transport channel and the second microfluidic pixel 3 of the pixel group 1.

In some embodiments, the cleaning liquid droplet 7 generated in the cleaning liquid droplet generation area X is controlled to clean the transport channel and the second microfluidic pixel 3 of the pixel group 1, and clean the transport channel in the transfer area Z and the second microfluidic pixel 3 of the pixel group 1. This cleaning process may avoid the residue of other liquid droplets containing the functional layer materials on the transport channel in the transfer area Z and the second microfluidic pixel 3 of the pixel group 1. Such residue may affect the subsequent transfer of the first liquid droplet 51, the second liquid droplet 52, and the third liquid droplet 53. This cleaning process may prevent other residual liquid droplets containing the functional layer materials from mixing with the first liquid droplet 51, the second liquid droplet 52, and the third liquid droplet 53 during the transfer process of the first liquid droplet 51, the second liquid droplet 52, and the third liquid droplet 53. Such residue may affect the structures of the organic light-emitting layer with the first color 431, the organic light-emitting layer with the second color 432, and the organic light-emitting layer with the third color 433 that are formed during preparation, thereby affecting the light-emitting performance of the organic light-emitting layers 43 with different colors.

In some embodiments, after moving the first liquid droplet 51 to the second microfluidic pixel 3 of the pixel group 1 through the liquid droplet entry area J and the transport channel in the operation at block S31, after moving the second liquid droplet 52 to the second microfluidic pixel 3 of the pixel group 1 through the liquid droplet entry area J and the transport channel in the operation at block S32, and after moving the third liquid droplet 53 to the second microfluidic pixel 3 of the pixel group 1 through the liquid droplet entry area J and the transport channel in the operation at block S33, the operation at block S301 and the operation 302 may be all performed. This ensures that before the transfer of the first liquid droplets 51, the second liquid droplets 52, and the third liquid droplets 53, the second microfluidic pixels 3 of the pixel groups and the transport channels in the transfer area Z and the liquid droplet entry area J are cleaned, thereby ensuring the transfer effect.

In some embodiments, after the operation at block S302, the structure illustrated in FIG. 27 may be obtained.

In some embodiments, as illustrated in FIG. 21, the liquid droplet input area Y further includes a blank area K communicated with the liquid droplet entry area J. After the operation of controlling the cleaning liquid droplet 7 to clean the transport channel and the second microfluidic pixel 3 of the pixel group 1, as described in the operation 302, the method for transferring the liquid droplets 5 may further includes: controlling the cleaning liquid droplet 7 to enter the blank area K.

In some embodiments, as illustrated in FIG. 21, two liquid droplet entry areas J are located on two opposite sides of the transfer area Z. Each of two cleaning liquid droplet generation areas X is located on the side of the corresponding liquid droplet entry area J away from the transfer area Z and communicated with the cleaning liquid droplet generation area X. Each of two blank areas K is also located on the side of the corresponding liquid droplet entry area J away from the transfer area Z. The blank area K is communicated with the liquid droplet entry area J but not communicated with the cleaning liquid droplet generation area X. After controlling the cleaning liquid droplets 7 to clean the second microfluidic pixels 3 of the pixel group 1 and the transport channel, that is, after the cleaning liquid droplets 7 in the two cleaning liquid droplet generation areas X pass over the second microfluidic pixels 3 of the pixel groups 1 and the transport channels in the transfer area Z, the cleaning liquid droplets 7 return to the blank area K. The blank area K is configured to accommodate the cleaning liquid droplet 7 after the cleaning liquid droplet 7 has cleaned the transport channel and the second microfluidic pixel 3 of the pixel group 1. This prevents the cleaning liquid droplet 7 containing other functional layer materials from directly returning to the first liquid droplet generation area C1, the second liquid droplet generation area C2, or the third liquid droplet generation area C3, because the cleaning liquid droplet 7 may contain other functional layer materials after cleaning. It also prevents the cleaning liquid droplet 7 containing other functional layer materials from directly returning to the cleaning liquid droplet generation area X. The cleaning liquid droplet 7 containing other functional layer materials may cause other functional layer materials to be in the first liquid droplet generation area C1, the second liquid droplet generation area C2, and the third liquid droplet generation area C3. Alternatively, it may lead to the mixing of other functional layer materials in the cleaning liquid droplet 7 in the cleaning liquid droplet generation area X. This contamination may affect the generation and transfer of the first liquid droplet 51, the second liquid droplet 52, and the third liquid droplet 53, as well as the cleaning effectiveness of the cleaning liquid droplet 7 on the transport channel and the second microfluidic pixel 3 of pixel group 1.

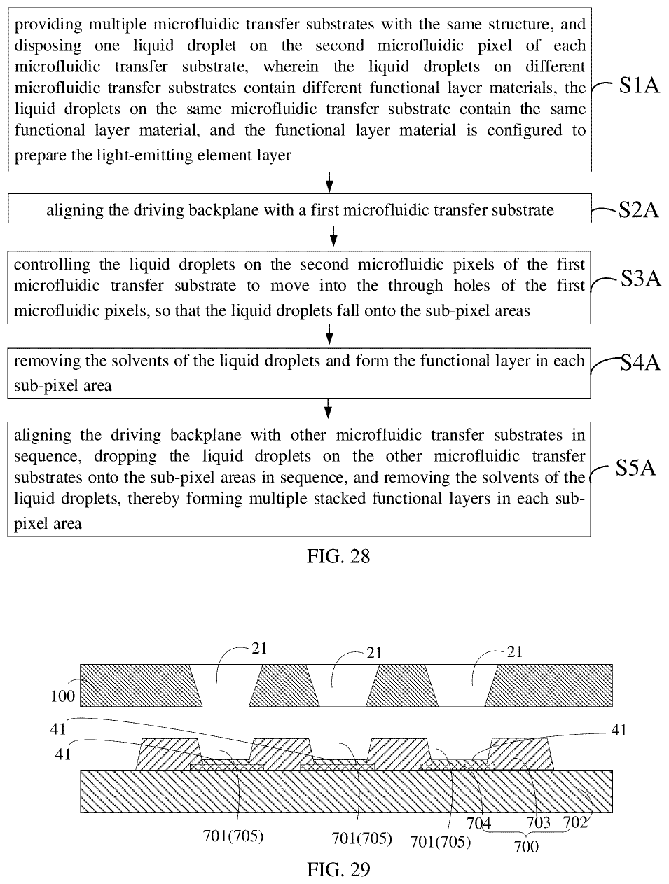

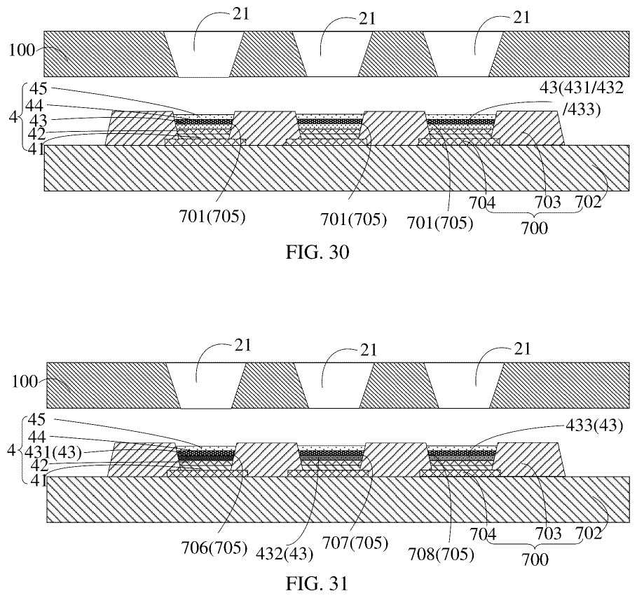

As illustrated in FIGS. 28 to 31, FIG. 28 is a flowchart of a second embodiment of a method for transferring the liquid droplets in the present disclosure. FIG. 29 is a structural schematic view of a structure corresponding to an operation at block S4A in the method for transferring the liquid droplets of FIG. 28 in an embodiment. FIG. 30 is a structural schematic view of a structure corresponding to an operation at block S5A in the method for transferring the liquid droplets of FIG. 28 in an embodiment. FIG. 31 is a structural schematic view of a structure corresponding to an operation at block S5A in the method for transferring the liquid droplets of FIG. 28 in another embodiment.

As illustrated in FIG. 28, the present disclosure further provides another method for transferring the liquid droplets 5. In some embodiments, the carrier substrate is the driving backplane 700, and the method for transferring the liquid droplets 5 is configured to prepare the display panel. In some embodiments, the method for transferring the liquid droplets 5 includes the following operations.

At block S1A, the method for transferring the liquid droplets 5 may include providing multiple microfluidic transfer substrates 100 with the same structure, and disposing one liquid droplet 5 on the second microfluidic pixel 3 of each microfluidic transfer substrate 100, wherein the liquid droplets 5 on different microfluidic transfer substrates 100 contain different functional layer materials, the liquid droplets 5 on the same microfluidic transfer substrate 100 contain the same functional layer material, and the functional layer material is configured to prepare the light-emitting element layer 4.

In some embodiments, the multiple microfluidic transfer substrates 100 are provided and have the same structure. The microfluidic transfer substrate 100 may be any one of the microfluidic transfer substrates 100 as described in the embodiments. One liquid droplet 5 is disposed on the second microfluidic pixel 3 of each microfluidic transfer substrate 100, as described in the operation at block S3 of the method for transferring the liquid droplets 5 in the first embodiment, which may not be repeated here. The liquid droplets 5 on different microfluidic transfer substrates 100 contain different functional layer materials. The liquid droplets 5 on the same microfluidic transfer substrate 100 contain the same functional layer material. That is, the liquid droplets 5 on the same microfluidic transfer substrate 100 form the same functional layer on the driving backplane 700, while the liquid droplets 5 on different microfluidic transfer substrates 100 form different functional layers on the driving backplane 700. The functional layer material is configured to prepare the light-emitting element layer 4 in the groove 701 of the driving backplane 700.

In some embodiments, as illustrated in FIG. 30, the light-emitting element layer 4 in the groove 701 is composed of five layers, namely a hole injection layer 41, a hole transport layer 42, the organic light-emitting layer 43, an electron transport layer 44, and an electron injection layer 45. The liquid droplets 5 on different microfluidic transfer substrates 100 contain different functional layer materials, so as to prepare different light-emitting element layers 4. The organic light-emitting layer 43 may be any one or more of the organic light-emitting layer with the first color 431, the organic light-emitting layer with the second color 432, and the organic light-emitting layer with the third color 433. The first color, the second color, and the third color may be red (R), green (G), and blue (B), respectively.

At block S2A, the method for transferring the liquid droplets 5 may include aligning the driving backplane 700 with a first microfluidic transfer substrate 100.

In some embodiments, the carrier substrate is the driving backplane 700, and the driving backplane 700 includes multiple sub-pixel areas 705. The driving backplane 700 is aligned with the first microfluidic transfer substrate 100 of the multiple microfluidic transfer substrates 100 in the operation at block S1A, so that the multiple through holes 21 of the first microfluidic transfer substrate 100 are aligned with and correspond to the multiple sub-pixel areas 705 of the driving backplane 700. The structure corresponding to the operation at block S2A may refer to the structure illustrated in FIG. 11a and FIG. 11b that corresponds to the operation at block S2 of the method for transferring the liquid droplets 5 in the first embodiment, which may not be repeated here.

At block S3A, the method for transferring the liquid droplets 5 may include controlling the liquid droplets 5 on the second microfluidic pixels 3 of the first microfluidic transfer substrate 100 to move into the through holes 21 of the first microfluidic pixels 2, so that the liquid droplets 5 fall onto the sub-pixel areas 705.

In some embodiments, after the operation at block S2A of aligning the driving backplane 700 with the first microfluidic transfer substrate 100, the liquid droplets 5 on the second microfluidic pixels 3 of the first microfluidic transfer substrate 100 are controlled to move into the through holes 21 of the first microfluidic pixels 2, so that the liquid droplets 5 fall onto the sub-pixel areas 705 of the driving backplane 700. The structure corresponding to the operation at block S3A may refer to the structure illustrated in FIG. 13a and FIG. 13b that corresponds to the operation at block S4 of the method for transferring the liquid droplets 5 in the first embodiment, which may not be repeated here.

At block S4A, the method for transferring the liquid droplets 5 may include removing the solvents of the liquid droplets 5 and form the functional layer in each sub-pixel area 705.

In some embodiments, drying and other operations may be performed on the liquid droplets 5 that fall onto the sub-pixel areas 705 of the driving backplane 700, so as to remove the solvents of the liquid droplets 5. In some embodiments, the thermal curing or the photo curing is configured to dry the liquid droplets 5 in the sub-pixel areas 705, so that the solvents of the liquid droplets 5 evaporate, and the liquid droplet 5 is converted into the solid film layer, forming the functional layer in each sub-pixel area 705 of the driving backplane 700.

In some embodiments, the liquid droplet 5 on the second microfluidic pixel 3 of the first microfluidic transfer substrate 100 is the liquid droplet 5 containing a hole injection material. The liquid droplet 5 moves into the through hole 21 of the first microfluidic pixel 2 and falls onto the sub-pixel area 705. After removing the solvent of the liquid droplet 5, the hole injection layer 41 is formed in the sub-pixel area 705.

In some embodiments, after the operation at block S4A, the structure illustrated in FIG. 29 may be obtained.

At block S5A, the method for transferring the liquid droplets 5 may include aligning the driving backplane 700 with other microfluidic transfer substrates 100 in sequence, dropping the liquid droplets 5 on the other microfluidic transfer substrates 100 onto the sub-pixel areas 705 in sequence, and removing the solvents of the liquid droplets 5, thereby forming multiple stacked functional layers in each sub-pixel area 705.

In some embodiments, the driving backplane 700 is sequentially aligned with the other microfluidic transfer substrates 100 in the operation at block S1A. The liquid droplets 5 are sequentially dropped from the other microfluidic transfer substrates 100 onto the sub-pixel areas 705, and the solvents of the liquid droplets 5 are removed, thereby forming multiple stacked functional layers in each sub-pixel area 705, so as to ultimately form the light-emitting element layer 4. The driving backplane 700 is aligned with one of the microfluidic transfer substrates 100, the liquid droplets 5 on the microfluidic transfer substrate 100 fall onto the sub-pixel areas 705 and the solvents of the liquid droplets 5 are removed. After forming the corresponding functional layer in each sub-pixel area 705, the driving backplane 700 is aligned with the next microfluidic transfer substrate 100 and the subsequent operations are performed, thereby sequentially forming different stacked functional layers. It is not necessary to first fall all the liquid droplets 5 of the microfluidic transfer substrate 100 onto the sub-pixel areas 705 and then remove the solvents of the liquid droplets 5 to form the stacked functional layers (i.e., the light-emitting element layer 4).

In some embodiments, five microfluidic transfer substrates 100 with the same structure are provided in the operation at block S1A, which are respectively configured to prepare and form the hole injection layer 41, the hole transport layer 42, the organic light-emitting layer 43, the electron transport layer 44, and the electron injection layer 45 in each sub-pixel area 705 of the driving backplane 700.

In some embodiments, after the operation at block S4A of removing the solvents of the liquid droplets 5 that fall from the first microfluidic transfer substrate 100 onto the sub-pixel area 705 to form the hole injection layer 41, the driving backplane 700 is aligned with a second microfluidic transfer substrate 100. The liquid droplets 5 on the second microfluidic pixels 3 of the second microfluidic transfer substrate 100 move into the through holes 21 of the first microfluidic pixels 2, so that the liquid droplets 5 fall onto the sub-pixel areas 705. In some embodiments, the liquid droplet 5 on the second microfluidic pixel 3 is the liquid droplet 5 containing a hole transport material, the solvent of the liquid droplet 5 is removed, so as to form the hole transport layer 42 that is disposed on a side of the hole injection layer 41 in the sub-pixel area 705. Then, the driving backplane 700 is aligned with a third microfluidic transfer substrate 100, and the liquid droplets 5 on the second microfluidic pixels 3 of the third microfluidic transfer substrate 100 move into the through holes 21 of the first microfluidic pixels 2, so that the liquid droplets 5 fall onto the sub-pixel areas 705. In some embodiments, the liquid droplet 5 on the third microfluidic transfer substrate 100 is the liquid droplet 5 containing the organic light-emitting material. The solvent of the liquid droplet 5 is removed, so as to form the organic light-emitting layer 43 that is stacked on a side of the hole transport layer 42 in the sub-pixel area 705. The organic light-emitting layer 43 may be any one of the organic light-emitting layer with the first color 431, the organic light-emitting layer with the second color 432, and the organic light-emitting layer with the third color 433. Then, the driving backplane 700 is aligned with a fourth microfluidic transfer substrate 100, and the liquid droplets 5 on the second microfluidic pixels 3 of the fourth microfluidic transfer substrate 100 move into the through holes 21 of the first microfluidic pixels 2, so that the liquid droplets 5 fall onto the sub-pixel areas 705. In some embodiments, the liquid droplet 5 on the fourth microfluidic transfer substrate 100 is the liquid droplet 5 containing an electron transport material. The solvent of the liquid droplet 5 is removed, so as to form the electron transport layer 44 that is stacked on a side of the organic light-emitting layer 43 in the sub-pixel area 705. Finally, the driving backplane 700 is aligned with a fifth microfluidic transfer substrate 100, and the liquid droplets 5 on the second microfluidic pixels 3 of the fifth microfluidic transfer substrate 100 move into the through holes 21 of the first microfluidic pixels 2, so that the liquid droplets 5 fall onto the sub-pixel areas 705. In some embodiments, the liquid droplet 5 on the fifth microfluidic transfer substrate 100 is the liquid droplet 5 containing an electron injection material. The solvent of the liquid droplet 5 is removed, so as to form the electron injection layer 45 that is stacked on side of the electron transport layer 44 in the sub-pixel area 705. After the operation at block S5A, the structure illustrated in FIG. 30 may be obtained.

In some embodiments, other quantities of microfluidic transfer substrates 100 may also be provided in the operation at block S1A. In some embodiments, fifteen microfluidic transfer substrates 100 may be provided in the operation at block S1A, and the multiple sub-pixel areas 705 of the driving backplane 700 may include the multiple first sub-pixel areas 706, the multiple second sub-pixel areas 707, and the multiple third sub-pixel areas 708.

In some embodiments, the structures of the first microfluidic transfer substrate 100 to the fifth microfluidic transfer substrate 100 are the same. In a case where the first microfluidic transfer substrate 100 to the fifth microfluidic transfer substrate 100 are aligned with the driving backplane 700, the multiple through holes 21 of the first microfluidic transfer substrate 100 to the fifth microfluidic transfer substrate 100 correspond one-to-one with the multiple first sub-pixel areas 706 of the driving backplane 700. By sequentially aligning the first microfluidic transfer substrate 100 to the fifth microfluidic transfer substrate 100 with driving backplane 700, then sequentially dropping the liquid droplets 5 on the first microfluidic transfer substrate 100 to the fifth microfluidic transfer substrate 100 onto the multiple first sub-pixel areas 706, and then removing the solvents of the liquid droplets 5, the hole injection layer 41, the hole transport layer 42, the organic light-emitting layer with the first color 431, the electron transport layer 44, and the electron injection layer 45 are sequentially formed in a stacked manner in each first sub-pixel area 706. Similarly, the structures of the sixth microfluidic transfer substrate 100 to tenth microfluidic transfer substrate 100 are the same. In a case where the sixth microfluidic transfer substrate 100 to tenth microfluidic transfer substrate 100 are aligned with the driving backplane 700, the multiple through holes 21 of the sixth microfluidic transfer substrate 100 to tenth microfluidic transfer substrate 100 correspond one-to-one with the multiple second sub-pixel areas 707 of the driving backplane 700. By sequentially aligning the sixth microfluidic transfer substrate 100 to tenth microfluidic transfer substrate 100 with the driving backplane 700, then sequentially dropping the liquid droplets 5 on the sixth microfluidic transfer substrate 100 to tenth microfluidic transfer substrate 100 onto the multiple second sub-pixel areas 707, and then removing the solvents of the liquid droplets 5, the hole injection layer 41, the hole transport layer 42, the organic light-emitting layer with the second color 432, the electron transport layer 44, and electron injection layer 45 are sequentially formed in the stacked manner in each second sub-pixel area 707. Similarly, the structures of the eleventh microfluidic transfer substrate 100 to the fifteenth microfluidic transfer substrate 100 are the same. In a case where the eleventh microfluidic transfer substrate 100 to the fifteenth microfluidic transfer substrate 100 are aligned with the driving backplane 700, the multiple through holes 21 of the eleventh microfluidic transfer substrate 100 to the fifteenth microfluidic transfer substrate 100 correspond one-to-one with the multiple third sub-pixel areas 708 of the driving backplane 700. By sequentially aligning the eleventh microfluidic transfer substrate 100 to the fifteenth microfluidic transfer substrate 100 with the driving backplane 700, then sequentially dropping the liquid droplets 5 on the eleventh microfluidic transfer substrate 100 to the fifteenth microfluidic transfer substrate 100 onto the multiple third sub-pixel areas 708, and then removing the solvents of the liquid droplets 5, the hole injection layer 41, the hole transport layer 42, the organic light-emitting layer with the third color 433, the electron transport layer 44, and the electron injection layer 45 are sequentially formed in the stacked manner in each third sub-pixel area 708. That is, the colors of the organic light-emitting layers 43 that are prepared in the first sub-pixel area 706, the second sub-pixel area 707, and the third sub-pixel area 708 of the driving backplane 700 are different. The first sub-pixel area 706 contains the organic light-emitting layer with the first color 431, the second sub-pixel area 707 contains the organic light-emitting layer with the second color 432, and the third sub-pixel area 708 contains the organic light-emitting layer with the third color 433. In some embodiments, after the operation at block S5A, the structure illustrated in FIG. 31 may be obtained.

The liquid droplets 5 containing the organic light-emitting materials with different colors are transferred to the first sub-pixel area 706, the second sub-pixel area 707, and the third sub-pixel area 708 of the driving backplane 700 through using different microfluidic transfer substrates 100, so that three different colored organic light-emitting layers 43 are formed in the three different sub-pixel areas 705.

In some embodiments, the multiple sub-pixel areas 705 of the driving backplane 700 may include the multiple first sub-pixel areas 706, the multiple second sub-pixel areas 707, and the multiple third sub-pixel areas 708. The same microfluidic transfer substrate 100 may be configured to prepare the hole injection layer 41 in each of the multiple first sub-pixel areas 706, the multiple second sub-pixel areas 707, and the multiple third sub-pixel areas 708 of the driving backplane 700. Similarly, the same microfluidic transfer substrate 100 may be configured to prepare the hole transport layer 42, the electron transport layer 44, and the electron injection layer 45 in each of the multiple first sub-pixel areas 706, the multiple second sub-pixel areas 707, and the multiple third sub-pixel areas 708 of the driving backplane 700, respectively. During only preparing the organic light-emitting layer with the first color 431 in each of the multiple first sub-pixel areas 706, the organic light-emitting layer with the second color 432 in each of the multiple second sub-pixel areas 707, and the organic light-emitting layer with the third color 433 in each of the multiple third sub-pixel areas 708, different microfluidic transfer substrates 100 are used. This not only achieves the preparation of the organic light-emitting layers 43 with different colors on the driving backplane 700, but also reduces the number of the microfluidic transfer substrates 100, thereby saving costs and improving the transfer efficiency of the liquid droplets 5 and the preparation efficiency of the display panel. The specific designs may be made according to needs, and may not be limited in the present disclosure.

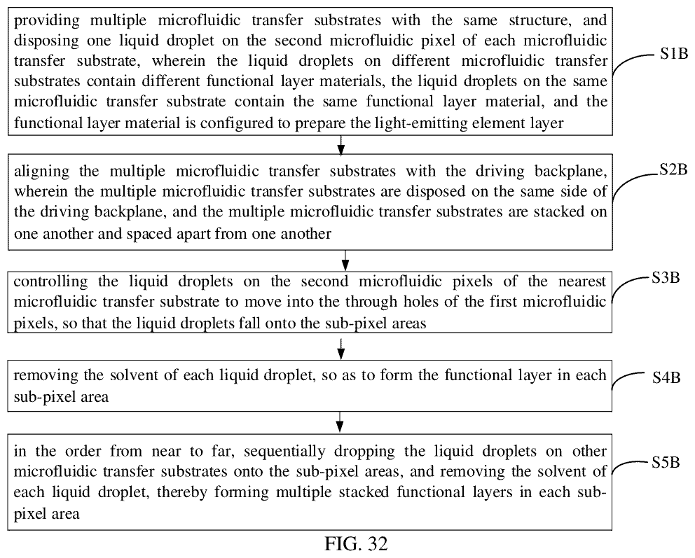

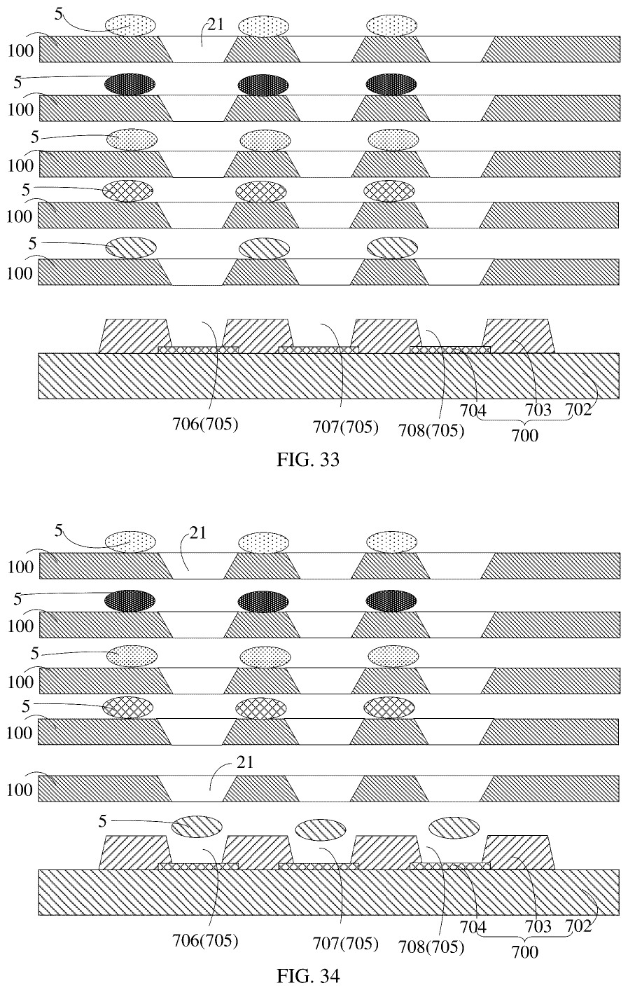

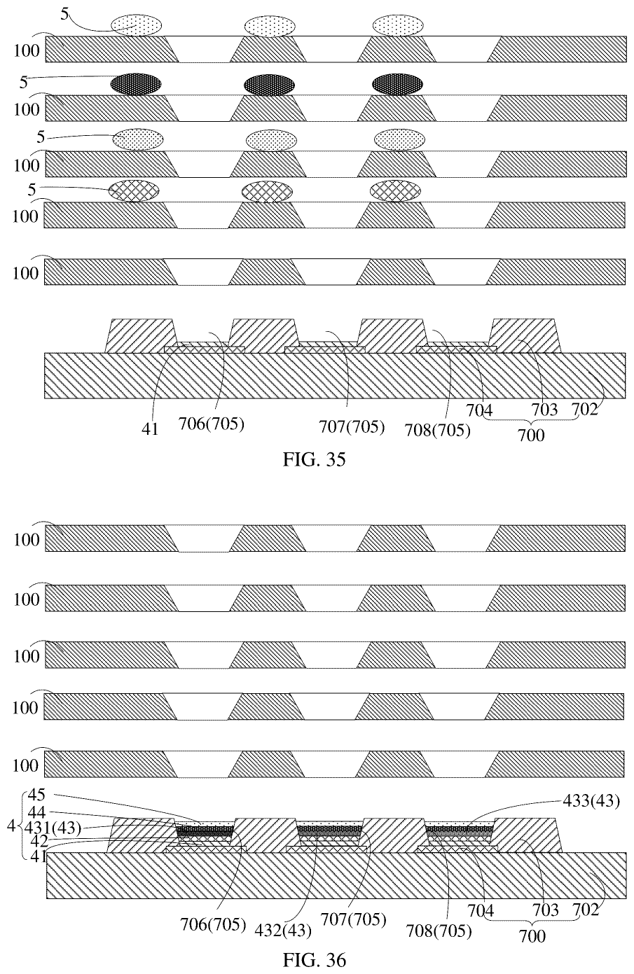

As illustrated in FIGS. 32 to 36, FIG. 32 is a flowchart of a third embodiment of a method for transferring the liquid droplets in the present disclosure. FIG. 33 is a structural schematic view of a structure corresponding to an operation at block S2B in the method for transferring the liquid droplets provided of FIG. 32 in an embodiment. FIG. 34 is a structural schematic view of a structure corresponding to an operation at block S3B in the method for transferring the liquid droplets provided of FIG. 32 in an embodiment. FIG. 35 is a structural schematic view of a structure corresponding to an operation at block S4B in the method for transferring the liquid droplets provided of FIG. 32 in an embodiment. FIG. 36 is a structural schematic view of a structure corresponding to an operation at block S5B in the method for transferring the liquid droplets provided of FIG. 32 in an embodiment.

As illustrated in FIG. 32, the present disclosure further provides another method for transferring the liquid droplets 5. In some embodiments, the carrier substrate is the driving backplane 700, and the method for transferring the liquid droplets 5 is configured to prepare the display panel. In some embodiments, the method for transferring the liquid droplets 5 includes the following operations.

At block S1B, the method for transferring the liquid droplets 5 may include providing multiple microfluidic transfer substrates 100 with the same structure, and disposing one liquid droplet 5 on the second microfluidic pixel 3 of each microfluidic transfer substrate 100, wherein the liquid droplets 5 on different microfluidic transfer substrates 100 contain different functional layer materials, the liquid droplets 5 on the same microfluidic transfer substrate 100 contain the same functional layer material, and the functional layer material is configured to prepare the light-emitting element layer 4.

In some embodiments, the operation at block S1B of the method for transferring the liquid droplets 5 may refer to the specific method in the operation at block S1A of the method for transferring the liquid droplets 5 in the second embodiment, which may not be repeated here.

At block S2B, the method for transferring the liquid droplets 5 may include aligning the multiple microfluidic transfer substrates 100 with the driving backplane 700, wherein the multiple microfluidic transfer substrates 100 are disposed on the same side of the driving backplane 700, and the multiple microfluidic transfer substrates 100 are stacked on one another and spaced apart from one another.

In some embodiments, different from the method for transferring the liquid droplets 5 in the second embodiment, in the third embodiment, the multiple microfluidic transfer substrates 100 are disposed on the same side of the driving backplane 700, the multiple microfluidic transfer substrates 100 are stacked on one another and spaced apart from one another, and the multiple microfluidic transfer substrates 100 are aligned with the driving backplane 700. In some embodiments, five microfluidic transfer substrates 100 with the same structure are provided in the operation at block S1B. The five microfluidic transfer substrates 100 are disposed on the same side of the driving backplane 700, the five microfluidic transfer substrates 100 are stacked on one another and spaced apart from one another, and the five microfluidic transfer substrates 100 are aligned with the driving backplane 700. In some embodiments, the multiple through holes 21 of the five microfluidic transfer substrates 100 are all aligned with the multiple sub-pixel areas 705 of the driving backplane 700. One liquid droplet 5 is disposed on the second microfluidic pixel 3 of each microfluidic transfer substrate 100. The liquid droplets 5 on the five microfluidic transfer substrates 100 contain different functional layer materials. In some embodiments, the liquid droplets 5 on the five microfluidic transfer substrates 100 include the liquid droplets 5 containing the hole injection materials, the liquid droplets 5 containing the hole transport materials, the liquid droplets 5 containing the organic light-emitting materials, the liquid droplets 5 containing the electron transport materials, and the liquid droplets 5 containing the electron injection materials. The liquid droplet 5 containing the organic light-emitting material may be any one of the liquid droplet 5 containing the organic light-emitting material with the first color, the liquid droplet 5 containing the organic light-emitting material with the second color, and the liquid droplet 5 containing the organic light-emitting material with the third color.

In one embodiment, after the operation at block S2B, the structure illustrated in FIG. 33 may be obtained.

At block S3B, the method for transferring the liquid droplets 5 may include controlling the liquid droplets 5 on the second microfluidic pixels 3 of the nearest microfluidic transfer substrate 100 to move into the through holes 21 of the first microfluidic pixels 2, so that the liquid droplets 5 fall onto the sub-pixel areas 705.

In some embodiments, the liquid droplets 5 on the second microfluidic pixels 3 of the nearest microfluidic transfer substrate 100 are controlled to move into the through holes 21 of the first microfluidic pixels 2, so that the liquid droplets 5 fall onto the sub-pixel area 705. The nearest microfluidic transfer substrate 100 is the microfluidic transfer substrate 100 with the smallest distance from the driving backplate 700. In some embodiments, after the operation at block S3B, the structure illustrated in FIG. 34 may be obtained.

At block S4B, the method for transferring the liquid droplets 5 may include removing the solvent of each liquid droplet 5, so as to form the functional layer in each sub-pixel area 705.

In some embodiments, the operation at block S4B of the method for transferring the liquid droplets 5 may refer to the specific method in the operation at block S4A of the method for transferring the liquid droplets 5 in the second embodiment, which may not be repeated here.

In some embodiments, after the operation at block S4B, the hole injection layer 41 is formed in each sub-pixel area 705, the structure illustrated in FIG. 35 may be obtained.

At block S5B, the method for transferring the liquid droplets 5 may include in the order from near to far, sequentially dropping the liquid droplets 5 on other microfluidic transfer substrates 100 onto the sub-pixel areas 705, and removing the solvent of each liquid droplet 5, thereby forming multiple stacked functional layers in each sub-pixel area 705.

In some embodiments, in the order from near to far, the liquid droplets 5 on other microfluidic transfer substrates 100 are sequentially dropped onto the sub-pixel areas 705, and the solvents of liquid droplets 5 are removed, thereby forming the multiple stacked functional layers in each sub-pixel area 705.

In some embodiments, the five microfluidic transfer substrates 100 with the same structure are provided in the operation at block S1B. The five microfluidic transfer substrates 100 are disposed on the same side of the driving backplane 700, the five microfluidic transfer substrates 100 are stacked on one another and spaced apart from one another, and the five microfluidic transfer substrates 100 are aligned with the driving backplane 700. The liquid droplets 5 on the five microfluidic transfer substrates 100 include the liquid droplets 5 containing the hole injection materials, the liquid droplets 5 containing the hole transport materials, the liquid droplets 5 containing the organic light-emitting materials, the liquid droplets 5 containing the electron transport materials, and the liquid droplets 5 containing the electron injection materials. In the order from near to far, the liquid droplets 5 containing the hole transport materials are sequentially dropped onto the sub-pixel areas 705, and the solvents of the liquid droplets 5 are removed, so as to the hole transport layer 42 on the side of hole injection layer 41. Then, the liquid droplets 5 containing the organic light-emitting materials fall onto the sub-pixel areas 705, and the solvents of the liquid droplets 5 are removed, so as to form the organic light-emitting layer 43 on the side of the hole transport layer 42. Then, the liquid droplets 5 containing the electron transport material fall onto the sub-pixel areas 705, and the solvents of the liquid droplets 5 are removed, so as to form the electron transport layer 44 on the side of the organic light-emitting layer 43. Finally, the liquid droplets 5 containing the electron injection materials fall onto the sub-pixel areas 705, and the solvents of the liquid droplets 5 are removed, so as to form the electron injection layer 45 on the side of electron transport layer 44.

In one embodiment, after the operation at block S5B, the structure illustrated in FIG. 36 may be obtained.

Different from the related art, the effects of the present disclosure are as follows. The present disclosure provides a microfluidic transfer substrate, a microfluidic transfer device, and a microfluidic transfer apparatus. The microfluidic transfer substrate includes a plurality of first pixel units. Some of the plurality of first pixel units serve as first microfluidic pixels, each first microfluidic pixel define a through hole, the others of the plurality of first pixel units serve as second microfluidic pixels, and each second microfluidic pixel is free of the through hole. Each first microfluidic pixel is adjacent to at least one second microfluidic pixel. By setting each first microfluidic pixel to have the through hole and disposing each first microfluidic pixel adjacent to at least one second microfluidic pixel, the preparation of the light-emitting element layer of the organic light-emitting diode display panel may be achieved by using the microfluidic transfer substrate. Therefore, the film-forming efficiency of the light-emitting element layer may be improved, and the problem of low film-forming efficiency of the light-emitting element layer of the organic light-emitting diode display panel in the related art may be solved.

The above descriptions are only some embodiments of the present disclosure, and are not intended to limit the protection scope of the present disclosure. Any equivalent structure or equivalent flow transformation made by using the contents and the accompanying drawings of the present disclosure, or directly or indirectly applied to other related technical fields, is included in the protection scope of the present disclosure.

1. A microfluidic transfer substrate, comprising:
a plurality of first pixel units, wherein some of the plurality of first pixel units serve as first microfluidic pixels, each first microfluidic pixel define a through hole, the others of the plurality of first pixel units serve as second microfluidic pixels, and each second microfluidic pixel is free of the through hole;
wherein each first microfluidic pixel is adjacent to at least one second microfluidic pixel.

2. The microfluidic transfer substrate according to claim 1, wherein
the plurality of first pixel units are divided into a plurality of pixel groups; and
each of the plurality of pixel group consists of one first microfluidic pixel and one second microfluidic pixel, or each of the plurality of pixel group consists of a plurality of first microfluidic pixels and one second microfluidic pixel.

3. The microfluidic transfer substrate according to claim 1, wherein
the plurality of first pixel units are arranged in a two-dimensional array; and
the first pixel units in odd-numbered rows are all the first microfluidic pixels, and the first pixel units in even-numbered rows are all the second microfluidic pixels and serve as transport channels; or in every three adjacent rows of first pixel units, the first pixel units in two outer rows are all the first microfluidic pixels, and the first pixel units in a middle row are all the second microfluidic pixels and serve as the transport channels.

4. The microfluidic transfer substrate according to claim 1, wherein
the plurality of first pixel units are arranged in a two-dimensional array;
in every three adjacent rows of first pixel units, the first pixel units in an outer row are all the second microfluidic pixels and serve as transport channels, while the first pixel units in the other two rows are divided into a plurality of pixel groups alternately arranged along a row direction; and
each of the plurality of pixel groups consists of three first microfluidic pixels and one second microfluidic pixel, and the three first microfluidic pixels of each of the plurality of pixel groups are adjacent to the one second microfluidic pixel.

5. The microfluidic transfer substrate according to claim 4, wherein
the plurality of first pixel units are rectangular, and each of the three first microfluidic pixels of each pixel group shares a side with the one second microfluidic pixel, and a pattern formed by two adjacent pixel groups is centrally symmetric.

6. The microfluidic transfer substrate according to claim 1, wherein
the plurality of first pixel units are arranged in a hexagonal close-packed distribution, and each of the plurality of first pixel units is a circle or a regular hexagon;
in every three adjacent rows of first pixel units, the first pixel units in an outer row are all the second microfluidic pixels and serves as transport channels, and the first pixel units in the other two rows are divided into a plurality of pixel groups alternately arranged along a row direction;
each of the plurality of pixel groups consists of three first microfluidic pixels and one second microfluidic pixel, the three first microfluidic pixels and the one second microfluidic pixel are arranged in two rows and two columns with a staggered configuration, and the three first microfluidic pixels of each pixel group are all adjacent to the one second microfluidic pixel.

7. The microfluidic transfer substrate according to claim 3, wherein
the microfluidic transfer substrate has a transfer area and a liquid droplet input area located on a side of the transfer area;
the plurality of first pixel units are disposed in the transfer area;
a plurality of second pixel units are disposed in the liquid droplet input area, the plurality of second pixel units have the same structure as the second microfluidic pixels; and
the liquid droplet input area is communicated with the transport channels, and configured for generating and transporting liquid droplets to the transfer area.

8. The microfluidic transfer substrate according to claim 1, wherein
each of the plurality of first pixel units comprises a substrate, a thin film transistor, a first insulation layer, a planarization layer, a microfluidic electrode layer, a second insulation layer, and a hydrophobic layer arranged in sequence;
the through hole sequentially penetrates through the substrate, the first insulation layer, the planarization layer, the microfluidic electrode layer, the second insulation layer, and the hydrophobic layer; and the through hole is arranged in a staggered manner with the thin film transistor.

9. A microfluidic transfer device, comprising:
a microfluidic transfer substrate, comprising:
a plurality of first pixel units, wherein some of the plurality of first pixel units serve as first microfluidic pixels, each first microfluidic pixel define a through hole, the others of the plurality of first pixel units serve as second microfluidic pixels, and each second microfluidic pixel is free of the through hole; and each first microfluidic pixel is adjacent to at least one second microfluidic pixel; and
a microfluidic control circuit, electrically connected to the microfluidic transfer substrate;
wherein the microfluidic control circuit is configured to control liquid droplet on the second microfluidic pixels to move into the through holes of the first microfluidic pixels.

10. The microfluidic transfer device according to claim 9, wherein
the plurality of first pixel units are divided into a plurality of pixel groups; and
each of the plurality of pixel group consists of one first microfluidic pixel and one second microfluidic pixel, or each of the plurality of pixel group consists of a plurality of first microfluidic pixels and one second microfluidic pixel.

11. The microfluidic transfer device according to claim 9, wherein
the plurality of first pixel units are arranged in a two-dimensional array; and
the first pixel units in odd-numbered rows are all the first microfluidic pixels, and the first pixel units in even-numbered rows are all the second microfluidic pixels and serve as transport channels; or in every three adjacent rows of first pixel units, the first pixel units in two outer rows are all the first microfluidic pixels, and the first pixel units in a middle row are all the second microfluidic pixels and serve as the transport channels.

12. The microfluidic transfer device according to claim 9, wherein
the plurality of first pixel units are arranged in a two-dimensional array;
in every three adjacent rows of first pixel units, the first pixel units in an outer row are all the second microfluidic pixels and serve as transport channels, while the first pixel units in the other two rows are divided into a plurality of pixel groups alternately arranged along a row direction; and
each of the plurality of pixel groups consists of three first microfluidic pixels and one second microfluidic pixel, and the three first microfluidic pixels of each of the plurality of pixel groups are adjacent to the one second microfluidic pixel.

13. The microfluidic transfer device according to claim 12, wherein
the plurality of first pixel units are rectangular, and each of the three first microfluidic pixels of each pixel group shares a side with the one second microfluidic pixel, and a pattern formed by two adjacent pixel groups is centrally symmetric.

14. The microfluidic transfer device according to claim 9, wherein
the plurality of first pixel units are arranged in a hexagonal close-packed distribution, and each of the plurality of first pixel units is a circle or a regular hexagon;
in every three adjacent rows of first pixel units, the first pixel units in an outer row are all the second microfluidic pixels and serves as transport channels, and the first pixel units in the other two rows are divided into a plurality of pixel groups alternately arranged along a row direction;
each of the plurality of pixel groups consists of three first microfluidic pixels and one second microfluidic pixel, the three first microfluidic pixels and the one second microfluidic pixel are arranged in two rows and two columns with a staggered configuration, and the three first microfluidic pixels of each pixel group are all adjacent to the one second microfluidic pixel.

15. The microfluidic transfer device according to claim 11, wherein
the microfluidic transfer substrate has a transfer area and a liquid droplet input area located on a side of the transfer area;
the plurality of first pixel units are disposed in the transfer area;
a plurality of second pixel units are disposed in the liquid droplet input area, the plurality of second pixel units have the same structure as the second microfluidic pixels; and
the liquid droplet input area is communicated with the transport channels, and configured for generating and transporting liquid droplets to the transfer area.

16. The microfluidic transfer device according to claim 9, wherein
each of the plurality of first pixel units comprises a substrate, a thin film transistor, a first insulation layer, a planarization layer, a microfluidic electrode layer, a second insulation layer, and a hydrophobic layer arranged in sequence;
the through hole sequentially penetrates through the substrate, the first insulation layer, the planarization layer, the microfluidic electrode layer, the second insulation layer, and the hydrophobic layer; and the through hole is arranged in a staggered manner with the thin film transistor.

17. A microfluidic transfer apparatus, comprising:
a microfluidic transfer device, wherein the microfluidic transfer device is configured to align with a driving backplane; and the microfluidic transfer device comprises:
a microfluidic transfer substrate, comprising:
a plurality of first pixel units, wherein some of the plurality of first pixel units serve as first microfluidic pixels, each first microfluidic pixel define a through hole, the others of the plurality of first pixel units serve as second microfluidic pixels, and each second microfluidic pixel is free of the through hole; and each first microfluidic pixel is adjacent to at least one second microfluidic pixel; and
a microfluidic control circuit, electrically connected to the microfluidic transfer substrate;
wherein the microfluidic control circuit is configured to control liquid droplet on the second microfluidic pixels to move into the through holes of the first microfluidic pixels;
a sealing assembly, configured to seal a space on a side of the microfluidic transfer substrate away from the driving backplane, and/or configured to seal a space between the microfluidic transfer substrate and the driving backplane; and
an air pump, configured to supply air to the space on the side of the microfluidic transfer substrate away from the driving backplane, and/or to evacuate the space between the microfluidic transfer substrate and the driving backplane.

18. The microfluidic transfer apparatus according to claim 17, wherein
the plurality of first pixel units are divided into a plurality of pixel groups; and
each of the plurality of pixel group consists of one first microfluidic pixel and one second microfluidic pixel, or each of the plurality of pixel group consists of a plurality of first microfluidic pixels and one second microfluidic pixel.

19. The microfluidic transfer apparatus according to claim 17, wherein
the plurality of first pixel units are arranged in a two-dimensional array; and
the first pixel units in odd-numbered rows are all the first microfluidic pixels, and the first pixel units in even-numbered rows are all the second microfluidic pixels and serve as transport channels; or in every three adjacent rows of first pixel units, the first pixel units in two outer rows are all the first microfluidic pixels, and the first pixel units in a middle row are all the second microfluidic pixels and serve as the transport channels.

20. The microfluidic transfer apparatus according to claim 17, wherein
the plurality of first pixel units are arranged in a two-dimensional array;
in every three adjacent rows of first pixel units, the first pixel units in an outer row are all the second microfluidic pixels and serve as transport channels, while the first pixel units in the other two rows are divided into a plurality of pixel groups alternately arranged along a row direction; and
each of the plurality of pixel groups consists of three first microfluidic pixels and one second microfluidic pixel, and the three first microfluidic pixels of each of the plurality of pixel groups are adjacent to the one second microfluidic pixel.
